(19) United States
(12) Patent Application Publication
(10) Pub. No.: US 2012/0273963 A1
(43) Pub. Date: Nov. 1, 2012

(54) MICROELECTRONIC INTERCONNECT SUBSTRATE AND PACKAGING TECHNIQUES

(76) Inventors: Uri Mirsky, Noflt (IL); Shimon Neftin, Kiryat Shmonah (IL); Lev Furer, Haifa (IL)

(21) Appl. No.: 13/426,910

(22) Filed: Mar. 22, 2012

Related U.S. Application Data
(63) Continuation-in-part of application No. 13/220,146, filed on Aug. 29, 2011.
Application No. 13/220,146 is a continuation of application No. 11/518,193, filed on Sep. 11, 2006, now abandoned.
(60) Provisional application No. 60/723,922, filed on Oct. 6, 2005.

(51) Int. Cl. H01L 21/768; H01L 23/48

(52) U.S. Cl. 257/774; 438/675; 257/E23.011; 257/E21.586

(57) ABSTRACT

There is provided herein an electrical cross-over comprising: a substrate having an upper surface and a lower surface; an electrically-conductive valve metal area extending from said upper surface to said lower surface; an electrical isolation structure extending from said upper surface to said lower surface and encompassing said electrically conductive area; a first electrically-conductive trace formed on a first electrical isolation area and at least traversing said electrically-conductive crossing area, and at least two second electrically-conductive traces each one of said at least two electrically-conductive traces is at least partially formed on a corresponding second electrical isolation area, wherein said each one of said at least second electrically-conductive traces at least partially extends into said crossing area thereby generating electrical conductivity between said at least two second electrically-conductive traces and said first electrically-conductive trace is electrically isolated from said at least two second electrically-conductive traces.

### CROSS-REFERENCE TO RELATED APPLICATIONS

The current application is a Continuation-in-Part application of U.S. patent application Ser. No. 13/220,146, which is a continuation of U.S. patent application Ser. No. 11/518,193, filed Sep. 11, 2006 which claims priority from U.S. Provisional Patent Application No. 60/723,922, filed Oct. 6, 2005.

### TECHNICAL FIELD

This application relates to microelectronic interconnect substrates and packaging techniques for electronic components, such as light emitting diodes (LEDs) and other high power microcircuits dies or modules.

### BACKGROUND

Microelectronics packaging and interconnection technologies have undergone both evolutionary and revolutionary changes to serve the trend towards miniaturization in electronics equipment, which is now very evident in military, telecommunications, industrial and consumer applications. The trend has been driven by various forces including specialist requirements for size and weight as well as cost and aesthetics, which have led to various innovative developments in packaging of integrated circuits and in connectivity on electronics substrates and circuit boards.

Examples of microelectronic devices which need to be packaged run the gamut from a simple light emitting diode (LED) die, which is basically a simple diode junction with two terminals, to a complex microprocessor (μP) integrated circuit chip (ICC, or IC) having a multitude of input and output terminals needed to be interfaced with other components.

In a broad sense, “microelectronic packaging” can simply be viewed as a way to interface an IC (or a die) with the “real” world of peripherals such as power sources (e.g., power supplies, batteries, and the like), input devices (e.g., keyboards, mouses, and the like), and output devices (e.g., monitors, modems, antennas, and the like). To do this, you need to connect the IC (or die) with the peripheral—basically, to get signals in and out of the IC, as well as to provide operating power to the IC—and this is typically done with wires or conductive traces on a printed wiring board (PWB).

In some simple semiconductor dies, as well as in most complex ICs, a major thermal management challenge is to reduce the thermal resistance of the thermal paths from the heat source—the die or IC—to the outside world wherefrom the heat can be taken away by air (or coolant) convection, conduction and by radiation. One major such thermal path, and at the front line of thermal resistance reduction effort, is in the direction of the substrate (the “board”, “chip carrier” or multi-layer (or multilayer) interconnect board carrier, substrate or interposer) on which the “hot” die(s) is (are) mounted. Such substrate can be a PWB (Printed Wired Board), a BGA (Ball Grid Array) substrate of various types. An example of a semiconductor die typically needing thermal management is light emitting diode (LED).

A major performance measure of light emitting diodes (LED) is photometric efficiency, namely, the conversion of input energy into visible light. Photometric efficiency is inversely proportional to the junction temperature of the LED. A major concern of LED packaging is keeping a die cool to provide good overall performance. The requirement to cool the LED devices by employing high thermal conductivity packaging is critical and grows in importance when employing LED arrays emitting high photometric energy. Commonly, high power LEDs and LED arrays are packaged on special heat-sink assemblies and employ various cooling approaches known to people skilled in the art of packaging high power microcircuits or LEDs.

Light emitting diodes (LEDs) are employed for a wide range of applications such as back light illumination for liquid crystal displays, vehicle lamp assemblies in automotive industry, various other displays and other light sources. Application areas have significantly grown and are continuing to significantly grow upon recent emergence of new generations of high power LEDs capable of emitting higher photometric energy.

Another consideration in LED packaging is directing the emitted light in the desired direction. This is often achieved by mounting the LED die within a cavity where the cavity walls act as a reflector and lens holder. Typically a cavity is filled with a polymeric transparent material acting both as a lens and sealant material. Adding some additives to the molding material is sometimes used to shift or filter the emitted light to achieve a desired light wavelength for a particular application.

Exemplary references describing LED packaging technologies may be found in U.S. Pat. Nos. 6,562,643; 6,274,924 and 6,603,258, incorporated in their entirety by reference herein.

Mention is made above of substrates (the “board”, “chip carrier” or multi-layer (or multilayer) interconnect board carrier, substrate or interposer) on which the “hot” die(s) is (are) mounted. Such substrate can, for example, be a PWB (Printed Wired Board) or a BGA (Ball Grid Array) substrate of various types. One function of an interconnect (or interconnection) substrate is to spread pitch—that is, to take connections which are relatively very close together (such as bond pads on an IC) and spread them out for connection to another device (such as a PWB or a BGA substrate). Another function is to translate one type of connection to another—for example from a wire bond from an IC-to-a solder bump for surface mounting a device.

There are many examples (or subsets) of interconnect substrates, one example is the “interposer”. Generally, an interposer provides electrical connections between an IC and a package, may perform a pitch spreading function, typically does not “translate” connection types (rather, has one connection type on both the “in” side and the “out” side), and often must provide a thermal management function.

A fundamental purpose of an interconnect substrate is, simply stated, to electrically connect two electronic components with one another. If, for example, you have a simple two terminal device (such as a simple resistor having two leads) poking through two holes on a PWB to conductors on the underside of the PWB, this is relatively straightforward, even if there is a conductive trace on the PWB which needs to pass under a body portion of the two terminal device (without connecting to it). However, with more complex electronic devices having many terminals (for example, input/output (I/O) connections) it is inevitable that there needs to be many crossovers to effect complex routing of signals (to a lesser extent, power). Solutions to this topological problem is multilayer interconnect technology.

To understand multilayer interconnect technology, imagine if you will (by way of analogy), transportation networks comprising roadways (roads, streets and highways), a subway system, and air traffic. Streets and highways are typically located on the earth's surface, and sometimes must cross one another. An intersection may be controlled by stop lights and stop signs, and traffic on one street must be interrupted to allow traffic on the cross-street to flow past—not a very useful concept in the electronic world. A bridge allows one road to pass over another, and traffic can flow without stoppage on each road without stoppage interference from the other road. The example of a bridge crossing a highway is analogous to early (1960s) transistor radios comprising a simple one-sided circuit board with one level of interconnect (patterned conductive traces on a back side of the circuit board). A “cross-over” was typically effected by a simple jumper wire—a “bridge”, so to speak, electrically connecting two conductive traces on the front side of the board.

Airplanes fly overhead (above ground level), unimpaired by road traffic (at ground level). Many airplanes are occupying the airspace, in various routes and at various altitudes. They can pass each other (with safe altitude separation) with ease. They are flying in different “layers”. The layers (and aircraft in them) can pass over and under one another with relative ease. But getting from an airplane in one layer to an airplane in another layer is not really feasible (a virtual impossibility. What would be needed would be some “magic” conduit between a route on one layer and a route in another layer, perhaps even to a layer separated by several intermediate layers. (It is acknowledged that on at least one occasion a stunt man has successfully skydived from one aircraft to another aircraft flying at a lower level. No analogy is perfect.)

In multilayer interconnect technology, there are several metal layers (of conductive traces) separated from one another by layers dielectric material. (Kind of like a layer cake, or lasagna.) Multilayer interconnect substrates with tens of alternating dielectric and conductive layers are not uncommon, and typically many layers are needed to effect complex routing schemes (schematically speaking, many cross-overs).

A key element in every multilayer interconnect technology is the “via”—an electrical connection between conductive traces of two adjacent metal layers separated by a dielectric material.

In conventional substrate technologies a dielectric sheet is used as base material, in which the vias are formed using drilling (etching or punching) and hole plating process. (A via is kind of like a metal eyelet for shoelaces.)

In multilayer substrate technology one type of via is the “blind” via which extends through a given dielectric layer(s) to a conductive trace on an inner metal layer, rather than completely through the entire substrate. Another blind via may extend through the remaining dielectric layers from a different position on the conductive trace, which could be useful for pitch spreading, or simply for effecting complex interconnections.

Vias provide electrical connectivity between conductive traces on two different (typically adjacent) metal layers, and also can serve a role in conducting heat away from an operating electronic device mounted on the substrate. Typically, with a dielectric-based substrate (such as a ceramic substrate), the vast bulk of the substrate is poor thermal conductivity ceramic material, in which case many vias can be formed and filled to improve the thermal conductivity.

ALOX™ substrate technology is described in the following patents and publications: U.S. Pat. No. 5,661,341; U.S. Pat. No. 6,448,510; U.S. Pat. No. 6,670,704; International Patent Publication No. WO 00/31797; International Patent Publication No. WO 04/049424.

ALOX™ substrate technology is a unique multilayer substrate technology developed for microelectronics packaging applications. The ALOX™ substrate technology does not require drilling and hole plating—the via is of solid full aluminum and the dielectric is of a high quality ceramic nature. The process is simple and low cost, and contains a low number of process steps. The ALOX™ substrate technology serves as a wide technology platform, and can be implemented in various electronics packaging applications such as for RF, SiP, 3-D memory stacks, MEMS and high power modules and components.

The starting material in the ALOX™ process is a conductive aluminum sheet. A first step in the process is masking the top and bottom of the sheet using conventional lithography techniques (for example, photoresist). Via structures are formed using anodization of the sheet through the whole thickness of the sheet. The exposed areas are converted into aluminum oxide which is ceramic in nature and a highly insulating dielectric material. The protected unexposed areas remain as aluminum elements—the connecting vias.

In its simplest form, an ALOX™ interconnect substrate is formed by electrochemical anodic oxidation of selected portions of an initially conductive valve metal (for example, aluminum) substrate resulting in areas (regions) of conductive (starting) material which are geometrically defined and isolated from one another by areas (regions) of anodized (non-conductive, such as aluminum oxide, or alumina) isolation structures. “Vertical” isolation structures extend into the substrate, including completely through the substrate. “Horizontal” isolation structures extend laterally across the substrate, generally just within a surface thereof. Anodizing from one or both sides of the substrate can be performed to arrive at complex interconnect structures.

In a more complex form (such as disclosed in U.S. Pat. No. 6,670,704) using this innovative process a multilayer low cost ceramic board is formed. A complete “three metal layer” core contains an internal aluminum layer, top and bottom patterned copper layers with though vias and blind vias incorporated in the structure. The ALOX™ technology offers a very simple and low cost production process; excellent thermal performance product, superior mechanical and electrical properties. The ALOX™ technology is illustrated in the following figures.

FIG. 1A illustrates a process flow 100 for via formation in an ALOX™ substrate, and the resulting via formed thereby, according to the prior art. Starting (a) with an aluminum layer or substrate, a masking material such as photoresist is applied (b) and patterned (c). Then, the unprotected aluminum is anodized (d), converting selected areas of the layer/substrate into non-conducting aluminum oxide.

Notice in step (d) that the anodizing proceeds partially anisotropically, extending slightly under the photoresist and also tapering in width from thickest at the top and bottom surfaces of the substrate to thinner within the body of the substrate. In step (d), anodization proceeds from both sides of the substrate. (In a situation involving a layer rather than a substrate, anodization would proceed from only an exposed side of the layer.) The resulting aluminum oxide is porous.

The photoresist is stripped (e), and resin is diffused into the porous oxide regions of the layer/substrate. For a substrate, resin can be diffused from both sides. (Theoretically, the substrate could be impregnated with resin before photoresist strip.) The result is an aluminum via extending completely through the substrate from one surface thereof to the opposite surface thereof, and the via is isolated from other such vias (not shown) by the insulating (and impregnated) aluminum oxide material. This is referred to by the assignee as the “core of cores”.

Next, metal interconnect layers of conductive traces (such as copper) are applied (f), using conventional technology to achieve what the assignee refers to as a “core”, which is a 3 metal layer structure. The process illustrated generally in FIG. 1A is shown and described in greater detail in U.S. Pat. No. 6,448,510.

FIG. 1B is a cross-sectional view of an ALOX™ substrate comprising a core having 3 metal layers. As illustrated therein, a substantially planar aluminum sheet having a nominal thickness T of 125-250 μm (microns) is anodized to create areas of modified aluminum oxide (Al2O3) bounding and defining a variety of aluminum structures comprising (from left to right in the figure) an internal aluminum layer (which can be used for power or ground), an aluminum via extending completely through the sheet from the top surface to the bottom surface thereof, and a blind/thermal via. The process illustrated generally in FIG. 1B is shown and described in greater detail in U.S. Pat. No. 6,670,704.

### Glossary

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).

ALOX™ A substrate technology (proprietary to Micro Components Ltd. of Ramat-Gabriel, Israel) wherein the substrate is metal based, made of a combination of aluminum metal and aluminum oxide based dielectric material forming a multi layer interconnect substrate, typically in a BGA format.

Aluminum Aluminium, or aluminum (Symbol Al)

Ampere (A) is the SI base unit of electrical current equal to one coulomb per second. It is named after Andre-Marie Ampere, one of the main discoverers of electromagnetism.

Angstrom (Å) a unit of measurement equal to 10 exp-10 meters (0.0000000001 meter). 10=1 nm (nanometer).

array a set of elements (usually referring to leads or balls in the context of semiconductor assembly) arranged in rows and columns

assembly the process of putting a semiconductor device or integrated circuit in a package of one form or another; it usually consists of a series of packaging steps that include: die preparation, die attach, wirebonding, encapsulation or sealing, deflash, lead trimming/forming, and lead finish

ball bond a bond that looks like a ball (generally spherical)

ball grid array (BGA) a surface-mount package that utilizes an array of metal spheres or balls as the means of providing external electrical interconnection, as opposed to the pin-grid array (PGA) which uses an array of leads for that purpose

CBGA short for ‘Ceramic Ball Grid Array’

chip A portion of a semiconductor wafer, typically containing an entire circuit which has not yet been packaged

chip-scale package (CSP) any package whose dimensions do not exceed the die's dimensions by 20%

coefficient of thermal expansion (CTE)—the fractional change in dimensions of a material per unit change in its temperature; usually expressed in parts per million per degree C.; also known as ‘thermal coefficient of expansion’ (TCE)

DC/DC Converter In electronics engineering, a DC to DC converter is a circuit which converts a source of Direct Current from one voltage to another. It is a class of power converter. DC to DC converters are important in portable electronic devices such as cellular phones and laptop computers, which are supplied with power from batteries. Such electronic devices often contain several subcircuits which each require unique voltage levels different than supplied by the battery (sometimes higher or lower than the battery voltage, or even negative voltage). Additionally, the battery voltage declines as its stored power is drained. DC to DC converters offer a method of generating multiple controlled voltages from a single variable battery voltage, thereby saving space instead of using multiple batteries to supply different parts of the device

die 1. a single chip from a wafer; 2. a small block of semiconductor material containing device circuitry.

die attach the assembly process step wherein the die is mounted on the support structure of the package, for example, the leadframe, die pad, cavity, or substrate

die used synonymously with “chip”. Plural, “dies” or “dice”.

earth (electrical) another name for “ground”

heat sink Devices used to absorb or transfer (conduct) heat away from heat sensitive devices or electronic components.

IC or ICC. short for Integrated Circuit, or Integrated Circuit Chip.

IGBT short for Insulated (sometimes called Isolated) Gate Bipolar Transistor. The IGBT combines the simple gate drive characteristics of the MOSFET with the high current and low saturation voltage capability of bipolar transistors by combining an isolated gate FET for the control input, and a bipolar power transistor as a switch, in a single device. The IGBT is mainly used in switching power supplies and motor control applications. The “first-generation” devices of the 1980s and early '90s were relatively slow in switching, and prone to failure through such modes as latchup and secondary breakdown. Second-generation devices were much improved, and the current third-generation ones are even better, with speed rivaling MOSFETs, and excellent ruggedness and tolerance of overloads. The extremely high pulse ratings of second- and third-generation devices also make them useful for generating large power pulses in areas like particle and plasma physics, where they are starting to supersede older devices like thyratrons and triggered spark gaps. Their high pulse ratings, and low prices on the surplus market, also make them attractive to the high-voltage hobbyist for generating large amounts of high-frequency power to drive experiments like Tesla coils. Availability of affordable, reliable IGBTs is a key enabler for electric vehicles and hybrid cars. Toyota's second generation hybrid Prius has a 50 kW IGBT inverter controlling two AC motor/generators connected to the DC battery pack.

Interconnect Substrate As used herein, an interconnect substrate is a typically flat substrate used to connect electronic components with one another and having patterns of conductive traces in at least one layer for effecting routing of signals (and power) from one electronic component to another, or to the outside world. Typically, an interconnect substrate has many metallization layers with the conductive traces, and vias connect selected traces from one layer to selected traces of another layer.

interposer an intermediate layer or structure that provides electrical connection between the die and the package

Inverter An Inverter is a circuit for converting direct current (DC) to alternating current (AC). Inverters are used in a wide range of applications, from small switched power supplies for a computer to large industrial applications to transport bulk power.

leadframe A metal frame used as skeleton support to provides electrical connections to a chip in many package types.

Light Emitting Diode (LED) A junction diode which give off light (and also generates some heat) when energized.

mask Broadly speaking, a mask is any material forming a pattern for a subsequent process to selectively affect/alter certain areas of a semiconductor substrate, and not others. Photoresist is a commonly-used masking material which is applied to the substrate, then washed off (stripped) after the desired process is completed.

MCM short for multi-chip module. In accordance with a basic definition and classification, given in “Thin film multichip modules” by George Messner, Iwona Turlik, John W. Balde and Philip E. Garrou, edited by the International Society for Hybrid Microelectronics, 1992, the multichip module is a device, which provides the interconnections for several chips that are subsequently protected by a coating or an enclosure. In accordance with different approaches and fabrication techniques the MCMs known today can be divided into 3 main groups:

MCM-C short for ‘Multi-Chip Module-Ceramic’. MCM-Cs are multichip modules which use sinterable metals to form the conductive patterns of signal and power layers, which are applied onto a substrate made of ceramic or glass-ceramic material.

MCM-L short for ‘Multi-Chip Module-Laminate’. MCM-Ls are multichip modules which use laminate structures and employ printed circuit technologies to form a pattern of signal and power layers, which are applied onto layers made of organic insulating material.

MCM-D short for ‘Multi-Chip Module-Dense’. MCM-Ds are multichip modules on which layers of metal and insulator are usually formed by the deposition of thin film onto a rigid support structure usually made of silicon, ceramic, or metal.

MEMS short for Micro Electro Mechanical Systems. MEMS micromachined in silicon, typically integrated with electronic microcircuits, generally fall into two categories of microsensors and microactuators; depending on application operation based on electrostriction, or electromagnetic, thermoelastic, piezoelectric, or piezoresistive effect.

microelectronics—The branch of electronics that deals with miniature (often microscopic) electronic components.

micron (μm) a unit of measurement equal to one millionth of a meter (0.000001 meter); also referred to as a micrometer.

mil a unit of measurement equal to 1/1000 or 0.001 of an inch; 1 mil=25.4 microns

molding the assembly process step wherein the devices are encapsulated in plastic; also referred to as ‘encapsulation’

nanometer (nm)—a unit of measurement equal to one billionth of a meter (0.000000001 meter).

package a container, case, or enclosure for protecting a (typically solid-state) electronic device from the environment and providing connections for integrating a packaged device with other electronic components.

photoresist or, simply “resist.” Photoresist (PR) is a photo-sensitive material used in photolithography to transfer a pattern from a mask onto a wafer. Typically, a liquid deposited on the surface of the wafer as a thin film then solidified by low temperature anneal. Exposure to light (irradiation) changes the properties of the photoresist, specifically its solubility. “Negative” resist is initially soluble, but becomes insoluble after irradiation. “Positive” resist is initially insoluble, but becomes soluble after irradiation. Photoresist is often used as an etch mask. In the context of the present disclosure, photoresist may be used as an oxidation mask.

Power Module A power electronic module provides the physical containment for several power components, usually Power semiconductor devices. This package provides an easy way to cool the devices and to connect them to the outer circuit. Classical example of structures available as power modules are:
switch (MOSFET, IGBT), with antiparallel Diode;
half bridge (inverter leg, with two switches and their corresponding diodes); and,
three-phases inverter (six switches and the corresponding diodes).

PWB short for printed wiring board. Also referred to as printed circuit board (PCB).

RF short for ‘Radio Frequency’. RF refers to that portion of the electromagnetic spectrum in which electromagnetic waves can be generated by alternating current fed to an antenna.

semiconductors—1. Any of various solid crystalline substances, such as germanium or silicon, having electrical conductivity greater than insulators but less than good conductors, and used especially as a base material for computer chips and other electronic devices. 2. An integrated circuit or other electronic component containing a semiconductor as a base material.

SI units The SI system of units defines seven SI base units: fundamental physical units defined by an operational definition, and other units which are derived from the seven base units, including:
kilogram (kg), a fundamental unit of mass
second (s), a fundamental unit of time
meter, or metre (m), a fundamental unit of length
ampere (A), a fundamental unit of electrical current
kelvin (K), a fundamental unit of temperature
mole (mol), a fundamental unit of quantity of a substance (based on number of atoms, molecules, ions, electrons or particles, depending on the substance)
candela (cd), a fundamental unit luminous intensity
degrees Celsius (° C.), a derived unit of temperature. t° C.=tK−273.15
farad (F), a derived unit of electrical capacitance
henry (H), a derived unit of inductance
hertz (Hz), a derived unit of frequency
ohm (Ω), a derived unit of electrical resistance, impedance, reactance
radian (rad), a derived unit of angle (there are 2π radians in a circle)
volt (V), a derived unit of electrical potential (electromotive force)
watt (W), a derived unit of power

SIP short for ‘System-in-a-Package’—a package that contains several chips and components that comprise a completely functional stand-alone electronic system (also acronym for ‘Single-in-Line Package’—a through-hole package whose leads are aligned in just a single row, but that definition is not used in the description herein)

SMD short for ‘Surface-Mount Device’

SMT short for ‘Surface-Mount Technology’
substrate 1. the base material of the support structure of an IC; 2. the surface where the die or other components are mounted during packaging; 3. the semiconductor block upon which the integrated circuit is built

surface-mount—a phrase used to denote that a package is mounted directly on the top surface of the board, as opposed to ‘through-hole’, which refers to a package whose leads need to go through holes in the board in order to get them soldered on the other side of the board
valve metal a metal, such as aluminum, which is normally electrically conductive, but which can be converted such as by oxidation to both a non-conductor (insulator) and chemical resistance material. Valve metals include aluminum (Al, including Al 5052, Al 5083, Al 5086, Al 1100, Al 1145, and the like), titanium, tantalum, also niobium, europium.

via A metallized or plated-through hole, in an insulating layer, for example, a substrate, chip or a printed circuit board which forms a conduction path itself and is not designed to have a wire or lead inserted therethrough. Vias can be either straight through (from front to back surface of the substrate) or “blind”. A blind via is a via that extends from one surface of a substrate to within the substrate, but not through the substrate.

Volt (V) A measure of “electrical pressure” between two points. The higher the voltage, the more current will be pushed through a resistor connected across the points. The volt specification of an incandescent lamp is the electrical “pressure” required to drive it at its designed point. The “voltage” of a ballast (for example 277 V) refers to the line voltage it must be connected to. A kilovolt (KV) is one thousand volts.

Voltage A measurement of the electromotive force in an electrical circuit or device expressed in Volts. It is often taught that voltage can be thought of as being analogous to the pressure (rather than the volume) of water in a waterline.

Watt (W) A unit of electrical power. Lamps are rated in watts to indicate the rate at which they consume energy. A kilowatt is 1000 watts.

Wavelength The distance between two neighboring crests of a traveling wave. The wavelength of (visible) light is between about 400 and about 700 nanometers.

wire bond Attachment of a tiny wire, as by thermocompression bonding or/and ultrasound, to a bonding pad on a semiconductor chip substrate bond finger.

wirebonding an assembly process or step that connects wires between the die and the bonding sites of the package (for example, the lead fingers of the leadframe or the bonding posts of the package)

### BRIEF DISCLOSURE (SUMMARY)

Generally, ALOX™ substrate technology is used as the substrate technology of choice to achieve a thermally enhanced package/substrate for LEDs and other high power devices packaging. In ALOX™ substrate technology, the substrate is metal based, made of a combination of aluminum metal and aluminum oxide based dielectric material forming a simple or a multilayer interconnect substrate, typically in a BGA format.

The ALOX™ substrate technology employs area selective anodization of aluminum substrates for forming patterned anodized areas defining corresponding patterned aluminum conductive areas. Such structures have low thermal resistance by virtue of a high aluminum content which can reach in some cases 85% (or more) of the volume. The dielectric material also have good thermal properties similar to those of pure aluminum oxide. Another advantage of these substrates is the ability to include aluminum filled vias for use as thermal and/or electrical vias according to a particular design.

As used herein, aluminum is exemplary of any number of “valve metal” starting materials that is initially a good electrical conductor, and which can be selectively converted to a non-conductive (insulating) material (such as, but not limited to aluminum oxide) by a process such as (but not limited to) electrochemical anodic oxidation resulting in conductive areas (regions) which are defined and isolated from one another by the insulting areas (regions).

Generally, the embodiments described herein relate to configuring an interconnect substrate and packaging in such a way to form a direct heat (thermal) path from an electronic component (such as an LED) mounted on a top (or front) surface of the substrate to the a bottom (or back) surface of the substrate. The thermal path zone comprises aluminum and metal layers, and is electrically isolated from other areas of the substrate.

Generally, diode reflectors may be integrally formed on the substrate.

Generally, interconnect cross-overs may be integrally formed on the substrate, using the ALOX™ substrate technology.

There is disclosed herein an assembly of an electronic component on an interconnect substrate comprising: an electronic component mounted to a top surface of the interconnect substrate; and a direct metal thermal path between the electronic component and the bottom surface of the substrate. The substrate may be a valve metal substrate which has been anodized to define at least one electrically isolated conductive area which extends completely through the substrate from the first surface thereof to a second surface thereof; and the at least one electrically isolated conductive area may comprise the direct metal thermal path between the electronic component and the bottom surface of the substrate. The electrically isolated conductive area may be defined by a vertical isolation ring extending through the substrate. The assembly may include a horizontal isolation area extending laterally across a surface of the substrate from one side of the vertical isolation ring towards an opposite side of the vertical isolation ring. The assembly may include first metallization on the top surface of the substrate; and second metallization on the bottom surface of the substrate.

There is disclosed herein an interconnect substrate comprising an aluminum substrate selectively anodized to form conductive areas electrically isolated from one another by isolation areas; and at least one conductive area is completely enclosed within the substrate by at least one isolation area.

There is disclosed herein a method for mounting an electronic component on an interconnect substrate comprising: providing a valve metal substrate; selectively anodizing the substrate to define at least one electrically isolated conductive area which extends completely through the substrate from the first surface thereof to a second surface thereof; forming a cavity in the first surface of the substrate; wherein the at least one electrically isolated conductive area is located within the cavity; and mounting an electronic component in the cavity. The valve metal may comprise aluminum. The electronic component may be an LED. The cavity may be filled with a polymeric transparent material.

There is disclosed herein a method of forming an interconnect substrate comprising: providing a valve metal substrate; selectively anodizing the substrate to define at least one electrically isolated conductive area which extends completely through the substrate from the first surface thereof to a second surface thereof; wherein: prior to anodizing, the substrate is thinned in selected areas. The anodization may be performed from only one side of the substrate. The anodization may be performed from both sides of the substrate.

There is disclosed herein an interconnect substrate for mounting electronic components comprising: a valve metal substrate which has been anodized to define at least one electrically isolated conductive area which extends completely through the substrate from the first surface thereof to a second surface thereof; a cavity formed in the first surface of the substrate; and wherein the at least one conductive area is located within the cavity.

There is disclosed herein a method of forming an interconnect substrate comprising: providing a valve metal substrate; selectively anodizing the substrate to form an isolation area upon which a conductive trace can be formed; and forming a conductive trace on the isolation area. The isolation area may have a width which is greater than a width of the conductive trace to ensure that the conductive trace is electrically isolated from the substrate.

There is disclosed herein a method of implementing cross-overs on an interconnect substrate using only one metallization layer (trace) comprising: providing an interconnection substrate having a surface, forming an electrically isolated conductive crossing area (crossing region) extending at least partially into the substrate from a surface thereof. The substrate may be a valve metal substrate; and the crossing area (crossing region) may be formed by selectively anodizing the substrate to form at least one electrically isolated conductive area which extends partially into the substrate from a surface thereof. The crossing area may have a generally circular shape. The crossing area may extend fully through the substrate to an opposite surface of the substrate. The crossing area may extend fully through the substrate to an opposite surface of the substrate in a thinned area of the substrate. The method may include forming a first isolation area in the surface of the substrate, traversing completely across the crossing area; and forming a first conductive trace disposed on the first isolation area. The method may include forming a second isolation area in the surface of the substrate comprising two segments, each segment extending onto the crossing area so that ends of the two segments are disposed on the crossing area and are separated from one another: and forming a second conductive trace comprising two trace segments, each of the two second conductive trace segments disposed on a corresponding one of the two second isolation areas, and each of the two second conductive trace segments having an end which extends beyond the end of the corresponding second isolation area onto the conductive crossing area such that ends of the two second conductive traces are electrically connected to the crossing area. The first and second conductive traces may be formed from a single layer of metallization, and are substantially coplanar with one another. The two second conductive trace segments may be collinear with one another.

There is disclosed herein an interconnect substrate comprising: a valve metal substrate; two local isolation areas extending into the substrate from a surface thereof, and extending along the surface of the substrate; and two conductive traces, each disposed on and extending along a respective on of the two local isolation areas. Two pads may be disposed on the surface of the substrate for attachment of electronic devices.

There is disclosed herein a method of selectively forming anodized areas in a valve metal substrate comprising: providing a valve metal substrate; forming at least one recess at a location in a surface of the substrate; and performing anodizing at the location of the recess. The at least one recess may be in the form of a ring groove in the surface of the substrate. The at least one recess may be in the form of a linear groove extending along the surface of the substrate. A plurality of recesses may be disposed in an array of appropriately spaced-apart recesses perforating the surface of the substrate. The recesses may extend only partially through the substrate. The recesses may extend fully through the substrate.

There is disclosed herein, according to some embodiments, an electrical cross-over device comprising: a substrate having an upper surface and a lower surface; an electrically-conductive valve metal crossing area extending from the upper surface to the lower surface; an electrical isolation structure extending from the upper surface to the lower surface and encompassing the electrically conductive crossing area; a first electrically-conductive trace formed on a first electrical isolation area and at least traversing the electrically-conductive crossing area, and at least two second electrically-conductive traces each one of the at least two electrically-conductive traces is formed on a corresponding second electrical isolation trace,
wherein the each one of the at least second electrically-conductive traces at least partially extends into the crossing area beyond corresponding second electrical isolation traces, thereby generating electrical conductivity between the at least two second electrically-conductive traces and the first electrically-conductive trace is electrically isolated from the at least two second electrically-conductive traces.

According to some embodiments, at least one of the corresponding second isolation areas may terminate in contact with the isolation structure. According to some embodiments, at least one of the at least two second conductive traces may include at least one expanded conduction region located within the crossing area. According to some embodiments, the corresponding second isolation area may abut the first isolation trace. According to some embodiments, the at least two second electrically-conductive traces may be coplanarly located on opposite sides of the first conductive trace. According to some embodiments, the at least two second electrically-conductive traces may be substantially in a parallel orientation to the first conductive trace. According to some embodiments, the at least two second electrically-conductive traces may be located on same side of the first conductive trace. According to some embodiments, the electrical isolation structure may have a geometrical shape the geometrical shape is selected from the group consisting of a rectangular cross-sectional are, a square cross-sectional area, a circular cross-sectional area, an ellipsoidal cross-sectional area, a polygonal cross-sectional area and any combination thereof. According to some embodiments, the electrical isolation structure may have a geometrical shape that varies between the upper surface and the lower surface. According to some embodiments, the electrical isolation structure may include a valve metal oxide. According to some embodiments, the crossing area may include a cavity.

There is disclosed herein, according to some embodiments, a method for electrical cross-over comprising: providing a valve metal substrate having an upper surface and a lower surface; selectively anodizing the substrate to form: a closed electrical isolation structure extending from the upper surface to the lower surface encompassing an electrically conductive area which extends from the upper surface to the lower surface; a first electrical isolation area traversing the electrically-conductive crossing area; and at least two second electrical isolation areas; applying a first metallization trace on the first electrical isolation area; applying at least two second metallization traces on the at least two second electrical isolation areas; wherein the each one of the at least second metallization traces at least partially extends into the crossing area thereby generating electrical conductivity between the at least two second metallization traces and the first metallization trace is electrically isolated from the at least two second metallization traces.

According to some embodiments, at least one of the second isolation areas terminates while connecting to the isolation structure. According to some embodiments, at least one of the at least two second metallization traces may include at least one conduction region located within the crossing area. According to some embodiments, the corresponding second isolation area may abut the first isolation area. According to some embodiments, the at least two second electrically-metallization traces may be coplanarly located on opposite sides of the first metallization trace. According to some embodiments, the at least two metallization layers are substantially in a parallel orientation to the first conductive trace. According to some embodiments, the at least two second metallization layers may be located on same side of the first metallization layer. According to some embodiments, the electrical isolation structure may have a geometrical shape the geometrical shape is selected from the group consisting of a rectangular cross-sectional are, a square cross-sectional area, a circular cross-sectional area, an ellipsoidal cross-sectional area, a polygonal cross-sectional area and any combination thereof. According to some embodiments, the electrical isolation structure as a geometrical shape that varies between the upper surface and the lower surface. According to some embodiments, the method may further include forming a cavity on at least one of the upper surface or the lower surface prior to the step of anodizing.

There is disclosed herein, according to some embodiments, an electrical cross-over device comprising: a substrate having an upper surface and a lower surface; a plurality of electrically-conductive crossing areas, each one of the plurality of crossing areas extends from the upper surface to the lower surface; a plurality of electrical isolation structures, each one of the plurality of electrical isolation structures extends from the upper surface to the lower surface and each one of the plurality of isolation structure encompasses at least one of the plurality of electrically conductive crossing areas; a first electrically-conductive trace formed on a first electrical isolation area and at least traversing the at least one of the plurality of crossing areas, and a plurality of sets of second electrically-conductive traces each set comprising at least two second electrically-conductive traces and each member of the set is at least partially formed on a corresponding second electrical isolation areas, wherein said each member of said set of at least second electrically-conductive traces at least partially extends into at least one of said plurality of said crossing areas thereby generating electrical conductivity between the members of the set at least two second electrically-conductive traces and the first electrically-conductive trace is electrically isolated from the each member of the set of at least two second electrically-conductive traces.

According to some embodiments, each one of the plurality of the electrical isolation structures may have a geometrical shape the geometrical shape is selected from the group consisting of a rectangular cross-sectional are, a square cross-sectional area, a circular cross-sectional area, an ellipsoidal cross-sectional area, a polygonal cross-sectional area and any combination thereof. According to some embodiments, each one of the electrical isolation may be structured as a geometrical shape that varies between the upper surface and the lower surface. According to some embodiments, one or more of said electrical isolation structures may include a valve metal oxide. According to some embodiments, each one of said electrical isolation structures may include a valve metal oxide. According to some embodiments, one or more of the plurality of crossing areas may include a cavity.

According to some embodiments, there is provided herein an electrical cross-over device comprising: a substrate having an upper surface and a lower surface; an electrically-conductive valve metal crossing area extending from the upper surface to the lower surface; an electrical isolation structure extending from the upper surface to the lower surface and encompassing the electrically conductive crossing area; a first electrically-conductive trace formed on a first electrical isolation area and at least traversing the electrically-conductive crossing area, and at least two second electrically-conductive traces each one of the at least two electrically-conductive traces is formed on a corresponding second electrical isolation trace,
wherein the each one of the at least second electrically-conductive traces at least partially extends into the crossing area beyond corresponding second electrical isolation traces, thereby generating electrical conductivity between the at least two second electrically-conductive traces and the first electrically-conductive trace is electrically isolated from the at least two second electrically-conductive traces.

According to some embodiments, at least one of the corresponding second isolation areas terminates in contact with the isolation structure. According to some embodiments, at least one of the at least two second conductive traces comprises at least one expanded conduction region located within the crossing area. According to some embodiments, the corresponding second isolation area abuts the first isolation trace. According to some embodiments, the at least two second electrically-conductive traces are coplanarly located on opposite sides of the first conductive trace. According to some embodiments, the at least two second electrically-conductive traces are substantially in a parallel orientation to the first conductive trace. According to some embodiments, the at least two second electrically-conductive traces are located on same side of the first conductive trace. According to some embodiments, the electrical isolation structure has a geometrical shape the geometrical shape is selected from the group consisting of a rectangular cross-sectional are, a square cross-sectional area, a circular cross-sectional area, an ellipsoidal cross-sectional area, a polygonal cross-sectional area and any combination thereof. According to some embodiments, the electrical isolation structure has a geometrical shape that varies between the upper surface and the lower surface. According to some embodiments, the electrical isolation structure comprises a valve metal oxide. According to some embodiments, the crossing area comprises a cavity.

According to some embodiments, there is provided herein a method for electrical cross-over comprising: providing a valve metal substrate having an upper surface and a lower surface;
selectively anodizing the substrate to form: a closed electrical isolation structure extending from the upper surface to the lower surface encompassing an electrically conductive area which extends from the upper surface to the lower surface; a first electrical isolation area traversing the electrically-conductive crossing area; and at least two second electrical isolation areas; applying a first metallization trace on said first electrical isolation area; applying at least two second metallization traces on said at least two second electrical isolation areas; wherein said each one of said at least second metallization traces at least partially extends into said crossing area thereby generating electrical conductivity between said at least two second metallization traces and said first metallization trace is electrically isolated from the at least two second metallization traces.

According to some embodiments, at least one of the second isolation areas terminates while connecting to the isolation structure. According to some embodiments, at least one of the at least two second metallization traces comprise at least one conduction region located within the crossing area. According to some embodiments, the corresponding second isolation area abuts the first isolation area. According to some embodiments, the at least two second electrically-metallization traces are coplanarly located on opposite sides of the first metallization trace. According to some embodiments, the at least two metallization layers are substantially in a parallel orientation to the first conductive trace. According to some embodiments, the electrical isolation structure has a geometrical shape the geometrical shape is selected from the group consisting of a rectangular cross-sectional are, a square cross-sectional area, a circular cross-sectional area, an ellipsoidal cross-sectional area, a polygonal cross-sectional area and any combination thereof. According to some embodiments, the electrical isolation structure as a geometrical shape that varies between the upper surface and the lower surface. According to some embodiments, the method further comprises forming a cavity on at least one of the upper surface or the lower surface prior to the step of anodizing.

### BRIEF DESCRIPTION OF THE DRAWINGS

Reference will be made in detail to preferred embodiments, examples of which may be illustrated in the accompanying drawing figures. The figures are intended to be illustrative, not limiting. Although the disclosure is generally described in the context of these preferred embodiments, it should be understood that it is not intended to limit the claims to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. Cross-hatching may or may not be used in cross-sectional views. If it is, the conventional standard of uniform thickness diagonal lines indicating conductor and alternating thin-thick lines indicating insulator may be used.

Elements of the figures are typically numbered as follows. The most significant digits (hundreds) of the reference number correspond to the figure number. For example, elements of FIG. 1 (FIG. 1, FIG. 1) are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, and the like Such relationships, if any, between similar elements in the same or different figures will become apparent throughout the specification, including, if applicable, in the claims and abstract.

FIG. 1A is a diagram of a process flow for via formation in an ALOX™ substrate, and the resulting via formed thereby, according to the prior art;

FIG. 1B is a cross-sectional view of an ALOX™ substrate, according to the prior art;

FIG. 2 is a cross-sectional view of an interconnect substrate, according to an embodiment of the invention. (The section is taken on a line F2-F2 through either of FIG. 3 or 4.);

FIG. 3 is a top view of the interconnect substrate of FIG. 2;

FIG. 4 is a bottom view of the interconnect substrate of FIG. 2;

FIG. 5 is a cross-section of an interconnect substrate, according to an embodiment of the invention;

FIG. 6A is a cross-section of an interconnect substrate, according to an embodiment of the invention;

FIG. 6B is a cross-section of an interconnect substrate, according to an embodiment of the invention;

FIG. 6C is a cross-section of an interconnect substrate, according to an embodiment of the invention;

FIG. 7 is a top view of an interconnect substrate, according to an embodiment of the invention;

FIG. 8 is a top view of a portion of the interconnect substrate of FIG. 7;

FIG. 9 is a cross-sectional view of a portion the interconnect substrate of FIG. 7. (The section is taken on a line F9-F9 through FIG. 8.);

FIGS. 10-16 are diagrams illustrating a process flow for forming the interconnect substrate of FIGS. 7-9;

FIG. 17 is a bottom view of an interconnect substrate, according to an embodiment of the invention;

FIG. 17A is a detailed cross-sectional view of a portion of the interconnect substrate of FIG. 17. (The section is taken on a line F17A-F17A through FIG. 17.);

FIG. 17B presents a three-dimensional view of the substrate of FIG. 17 showing the locations of the conductive traces and their respective isolation areas, in accordance with another preferred embodiment of the present invention;

FIG. 18 is a cross-sectional view of the interconnect substrate of FIG. 17. (The section is taken on a line F18-F18 through FIG. 17.);

FIG. 19 is a cross-sectional view of the interconnect substrate of FIG. 17. (The section is taken on a line F19-F19 through FIG. 17.);

FIG. 20 is a bottom view of an interconnect substrate, according to an embodiment of the invention;

FIG. 21 is a cross-sectional view of the interconnect substrate of FIG. 20. (The section is taken on a line F21-F21 through FIG. 20.);

FIG. 22 is a top view of an interconnect substrate, according to an embodiment of the invention;

FIG. 23 is a bottom view of an interconnect substrate, according to an embodiment of the invention;

FIG. 24 is a cross-section of the interconnect substrate of FIGS. 22 and 23. (The section is taken on a line F21-F21 through FIGS. 22 and 23.);

FIG. 25 is a cross-sectional view of an interconnect substrate, according to an embodiment of the invention. (The section is taken on a line F25-F25 through FIG. 26.);

FIG. 26 is a top view of the substrate of FIG. 25;

FIG. 27 is a cross-sectional view of an interconnect substrate, according to an embodiment of the invention;

FIGS. 28-30 are diagrams illustrating a process flow for forming the interconnect substrate of FIG. 27;

FIG. 31 presents a view of a base of a substrate, in accordance with another preferred embodiment of the present invention;

FIG. 31A presents a three-dimensional view of the substrate of FIG. 31 showing the locations of the conductive traces and their respective isolation areas, in accordance with another preferred embodiment of the present invention;

FIG. 31B presents a further three-dimensional view of the substrate of a substrate showing the locations of the conductive traces and their respective isolation areas, in yet another preferred embodiment of the present invention;

FIG. 32 presents a vertical cross-sectional portion of the substrate of FIG. 31 in the direction of the arrows A-A, in accordance with another preferred embodiment of the present invention;

FIG. 33 presents a vertical cross-section of the substrate of FIG. 31 in the direction of arrows B-B, in accordance with another preferred embodiment of the present invention;

FIG. 34 presents a vertical cross-section of the substrate of FIG. 31 in the direction of arrows C-C, in accordance with another preferred embodiment of the present invention;

FIG. 35 presents a view of a base of a substrate, in accordance with yet another preferred embodiment of the present invention;

FIG. 36 presents a view of a base of a substrate, in accordance with a further preferred embodiment of the present invention;

FIG. 37 presents a view of a base of a substrate, in accordance with yet a further preferred embodiment of the present invention;

FIG. 38 presents a view of a base of a substrate, in accordance with yet another further preferred embodiment of the present invention;

FIG. 39 presents a view of a base of a substrate, in accordance with yet another preferred embodiment of the present invention, and

FIG. 40 shows a view of a substrate including at least a first and second vertical isolation structures and at least a first and second crossing areas, in accordance with yet another preferred embodiment of the present invention.

### DETAILED DESCRIPTION

The disclosure relates to interconnect substrates, such as ceramic substrates, and to packaging electronic components, such as light emitting diodes (LEDs) and other high power microcircuits dies or modules.

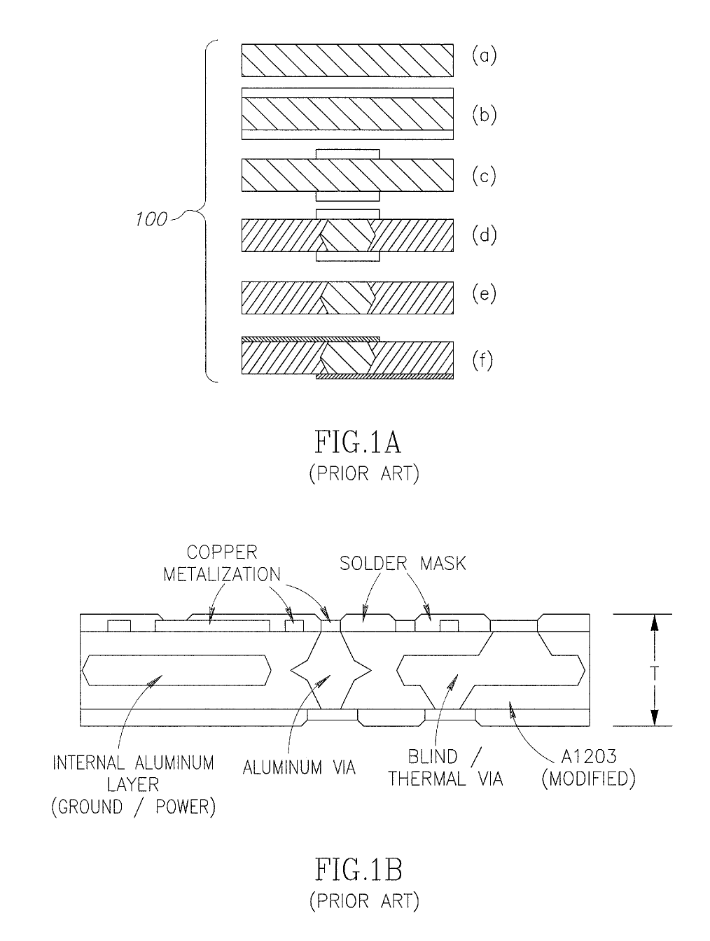

FIGS. 1A and 1B, described hereinabove, disclose the ALOX™ technology, generally. As discussed hereinabove, the ALOX™ substrate technology is a unique multilayer substrate technology developed for microelectronics packaging applications.

Several embodiments will now be described, using examples of mounting electronic components that generate heat, such as LEDs, on an interconnect substrate, integrating reflectors for the LEDs into the interconnect substrate, and effecting simple cross-overs of conductive lines on the interconnect substrate. ALOX™ technology is used as an exemplary technology for implementing the various embodiments described herein.

### Embodiment 1

### Direct Metal Connection between Die and Bottom of Substrate

The basic approach of this embodiment for assembly of a high power device (electronic component) such as an LED die or array of dies is to mount the device(s) onto a flat carrier (interconnect substrate) including an interconnect metallization pattern connecting the various dies on the substrate to each other and/or to input and output leads. The challenge is to employ a carrier having good (high) thermal conductivity between the die(s) and the bottom of the substrate from whence heat may conveniently be extracted. An ALOX™ based substrate is suitably and advantageously employed for this purpose.

As will become evident, a key advantage and feature of this embodiment is that the electronic component is mounted atop an aluminum metal area of the substrate, and the direct (straight line, shortest distance between two points) thermal path between the electronic component and the bottom of substrate does not include any intervening dielectric material layer.

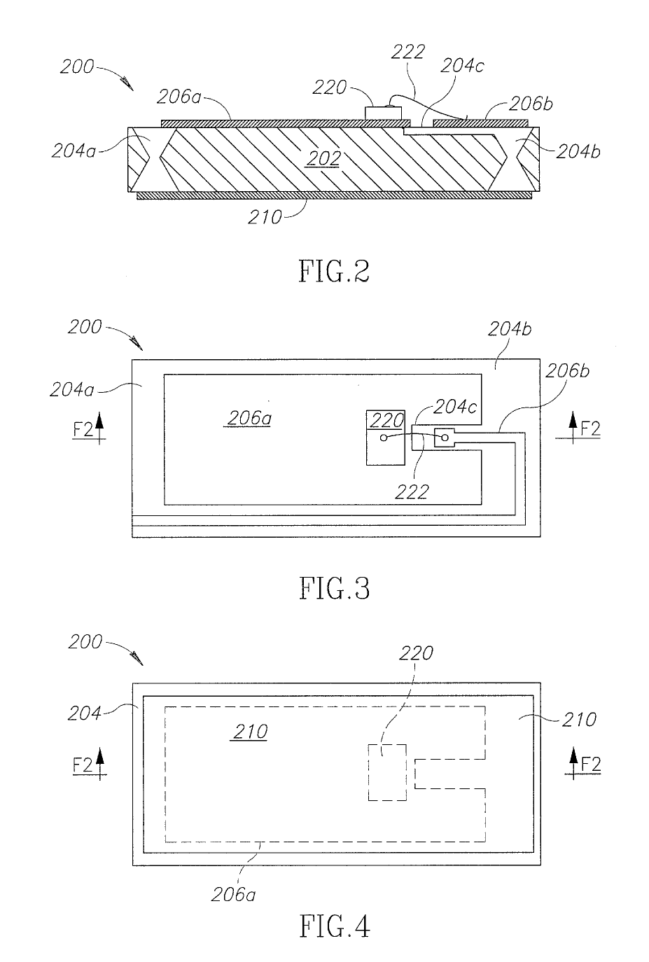

A first embodiment is shown and described with respect to FIGS. 2A-2E using an example of mounting (assembling) electronic components such as individual dies which are LEDs or other high power devices assembled on an ALOX™-based substrate and having a direct metal electrical connection and thermal path between the electronic component and the bottom surface of the interconnect substrate. Ultimately, the substrate with die mounted thereon can be mounted atop a heat sink (not shown) so that the heat conducted through the substrate can be dissipated by the heat sink. The substrate can be integrated with a heat sink—can be thermally directly contacted to cooling environment: cooling flowing liquid, gas, heat pipes and others.

The exemplary embodiment is an interconnection substrate 200 with an LED 220 (exemplary of a plurality of LEDs) assembled onto it. Generally, the substrate 200 includes an area (or region) of vertical isolation 204 (shown as vertical isolation 204a and vertical isolation 204b) comprising ALOX™ (impregnated porous aluminum oxide) material that surrounds (thereby defining) an aluminum conductive area (or region) 202 on which the die 220 is mounted. Using such vertical isolation (structure) around an aluminum area underneath the die provides both the direct metal thermal path and the electrical isolation required for interconnecting the die to other dies on the substrate.

The substrate 200 is essentially a flat slab or sheet of aluminum converted to an interconnect substrate using the ALOX™ technology. The substrate 200 has a top (as viewed), or front surface and a bottom (as viewed) or back surface. The substrate 200 includes:
an aluminum conductive region 202, extending completely through the substrate 200, having a top surface and a bottom surface which are the top and bottom surfaces, respectively, of the substrate 200; and
an aluminum oxide vertical isolation region (or structure) 204 which surrounds and electrically isolates the aluminum conductive region 202.

In the cross-section of FIG. 2 the vertical isolation region 204 is shown having a left (as viewed) portion 204a and a right (as viewed) portion 204b. As best viewed in FIG. 3, the vertical isolation region 204 is a “closed” structure, for example, like a ring (or frame), defining and surrounding (and electrically isolating) the distinct aluminum conductive region 202 which is like and island. The vertical isolation region 204 is suitably formed within the substrate 200 using the ALOX™ process, and extends completely through the substrate, from the top to the bottom surfaces of the substrate.

The geometric shape of the isolation structure 204 may be generally rectangular as shown, circular, elliptical, or any may have other shape or form.

By way of example, and to put things in perspective,
the aluminum conductive region 202 is 50-500 μm, such as 50-300 μm thick (vertical dimension, as shown), and
the vertical isolation region 204 tapers from 150-350 μm wide (horizontal dimension, as shown) at the surface of the substrate to 50-100 μm wide within the substrate. In this example, the inner diameter of the ring formed by the vertical isolation region 204 is 3-4 mm.

The aluminum conductive region 202 may be about 3-4 mm wide, which is ample space for mounting an electronic component such as an LED 220.

The taper of the vertical isolation region 204 is essentially an “artifact” of the ALOX™ process. It is within the scope of this disclosure that the vertical isolation region would be straight rather than tapered, and that the taper angle can be controlled.

The primary function of the vertical isolation region 204 is to electrically isolate the aluminum conductive region 202 from the remainder (rest) of the substrate, and from other aluminum conductive regions which may be formed by other vertical isolation regions (not shown), as well as from anything outside the ring (or any closed structure) of the vertical isolation region 204. The geometry of the vertical isolation region has no significant mechanical function, but since it is tapered, it does have the ability to mechanically “lock” the conductive region 202 within the substrate (in the manner of a dovetail joint).

The aluminum conductive region 202 can, in a sense, be thought of as a huge via providing electrical connectivity (and a direct thermal path) between the top surface of the substrate 200 and the bottom surface of the substrate for an electronic component mounted atop the substrate, and also performs the important function of a heatsink (and thermal capacity) for an electronic component (for example, LED) mounted atop the substrate. This is exemplary of where the ALOX™ provides results that would otherwise be difficult to achieve.

Optionally, the substrate 200 includes:
an aluminum oxide surface (horizontal) isolation region (area, structure, ring) 204c extending laterally across the substrate from the one side 204b of the vertical isolation ring (204) towards the opposite side 204a of the ring, within the top surface of the substrate 200. By way of example, the horizontal isolation region 204c is 40 μm thick, and extends a fraction, such as 20-30% of the distance across the aluminum conductive region 202 within the vertical isolation ring 204. Generally, the purpose of the horizontal isolation region 204c is simply so that there is more room (surface area) for the conductive area 206b (described below) to sit on the substrate without contacting the conductive region 202. (In other embodiments, described hereinbelow, such a horizontal isolation region is important for electrically isolating overlying conductive traces from the substrate.)

According to some embodiments, a horizontal isolation region generally extends only partially into the substrate, from a surface thereof, and their general purpose is to provide a surface area which is electrically isolated from underlying aluminum. One or both surfaces of the substrate can be provided with horizontal isolation regions. (See, for example, 604c and 604d in FIG. 6A.)

Top metallization is disposed on the top surface of the substrate—two conductive areas 206a and 206b (collectively referred to as 206) are shown. (The conductive “area” 206b is more like what one would expect a conductive “trace” to look like. The conductive “area” 206a is more like what one would expect a conductive “pad” to look like.) The top metallization may be copper, applied as a blanket layer using conventional sputtering and electroplating processing techniques and having a thickness of 2-50 μm, such as 12-20 μm 1-50 μm, and patterned using conventional photolithographic processing techniques (for example, resist, selective etch, strip, and the like).

One conductive area 206a extends from adjacent or partially on (as shown) the top of the vertical isolation portion 204a towards the vertical isolation portion 204b, and is in direct contact with the aluminum conductive region 202. Preferably, the conductive area 206a extends completely across the aluminum conductive region 202 to slightly atop the horizontal isolation portion 204c. Although it is not necessary from an electrical viewpoint that the conductive area 206 extend completely across the aluminum conductive region 202, it is generally desirable to entirely cover (prevent from being exposed) the underlying aluminum conductive region (202) because of galvanic considerations. Hence, the conductive area 206a preferable spans the entire distance between the vertical isolation portion 204a and the horizontal isolation region 204c.

The other conductive area 206b is disposed directly and solely on (atop) the vertical isolation portion 204b and horizontal isolation portion 204c and is not in contact with the aluminum conductive region 202.

Bottom metallization is disposed on the bottom surface of the substrate 200—one conductive area 210 is shown. The bottom metallization may be copper, having a thickness of 1-50 μm, such as 15-20 μm patterned using conventional photolithographic processing techniques. The bottom metallization is in direct contact with the aluminum region 202, and extends from partially on the bottom of the vertical isolation portion 204a, entirely across the aluminum region 202 between the two vertical isolation portions 204, to partially on the bottom other vertical isolation portion 204b. (For the same reasons as stated above, it is preferred to completely cover the aluminum region 202 to prevent it from being exposed, because of galvanic considerations.) The bottom metallization may be thicker than the top metallization to provide more thermal mass for spreading heat in the x-y direction (parallel to the plane of the substrate).

An electronic component 220, such as an LED is mounted atop the conductive area (pad) 206a of the top metallization 206 and is connected, such as with a bond wire 222 to the conductive area 206b (trace) of the top metallization 206. Mounting and bonding are effected using conventional techniques.

Using vertical isolation 204 around the aluminum region 202 underneath the die 220 provides both direct metal thermal path through the substrate 200 and the electrical isolation required for interconnecting the die to other electronic components (not shown) in the circuit.

As used herein, according to some embodiments, “direct thermal path” means that there is only metal such as, copper-aluminum-copper, layers of copper, nickel and gold, a single layer of aluminum or layers of vanadium and aluminum, and without insulating material such as aluminum oxide, titanium oxide or tantalum oxide, between the die which is mounted to the front surface of the substrate and a corresponding underlying area on the back surface of the substrate.

Additionally, the aluminum conductive region (202) can be much larger than the footprint of the die (220), such as at least 5, at least 10, at least 20 times larger.

FIG. 3 is a top view of the interconnect substrate 200 of FIG. 2. In this figure, the vertical isolation 204 (204a, 204b, 204c) is clearly seen surrounding the aluminum core area 202. Also, a pad area (for wire-bonding) is formed at the end of conductive line (metallization trace) 206b. As can be seen, the horizontal extension 204c occupies minimal area on top of the metal core 202.

FIG. 4 is a bottom view of the interconnect substrate 200 of FIG. 2. This figure illustrates the large metal pad 210 connected to the aluminum core 202 and directly thermally coupled to the die 220.

### Forming an Internal Aluminum Layer

FIG. 1B showed an internal aluminum layer, which typically can be used for ground or power. As evident from the blind thermal via, an internal aluminum layer should eventually surface at the top and or bottom surface of the substrate. However, it may also be useful to have an internal aluminum layer which is completely enclosed (within the substrate) and not electrically connected to anything, for thermal management.

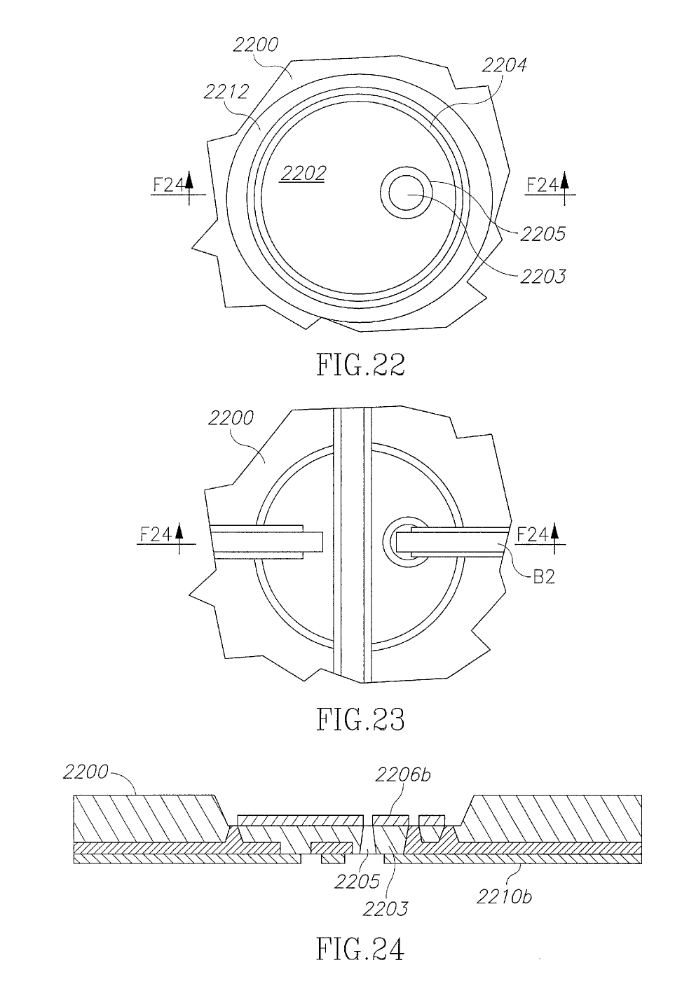

FIG. 22 of the aforementioned U.S. Pat. No. 6,670,704 shows a device having an electrically insulated aluminum trace (112) embedded therein. The trace portion (113) is buried within the solid body (104) of the substrate. Ends of the trace emerge at the top and bottom surfaces of the substrate.

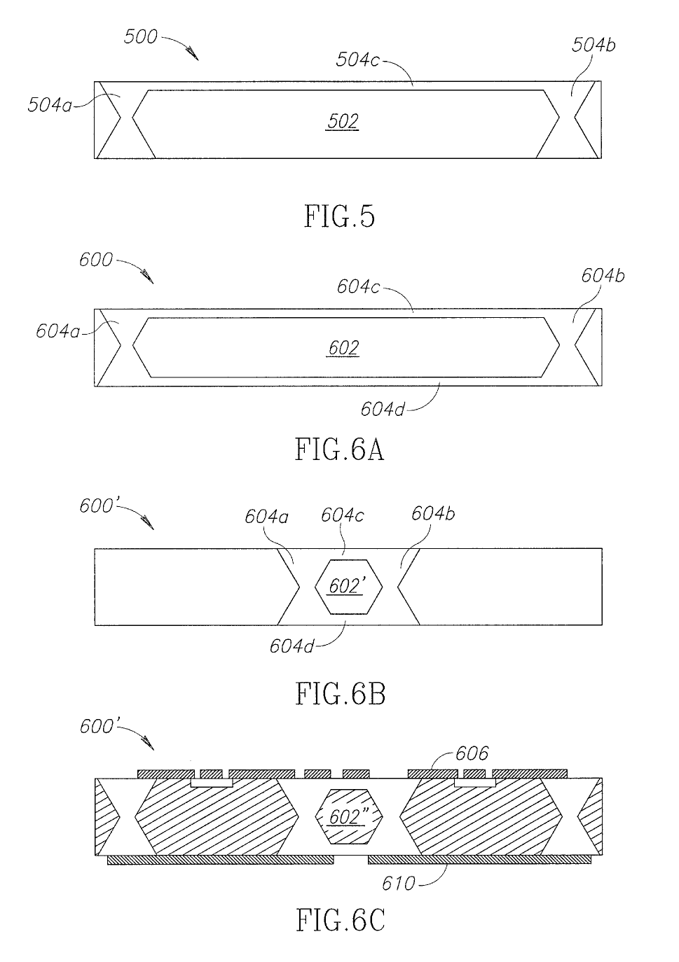

FIG. 5 illustrates a substrate 500 formed using ALOX™ technology, and is similar to FIG. 2. A vertical isolation area is shown having a one side portion 504a (compare 304a) and an opposite side portion 504b (compare 204b) surrounds (and defines) an aluminum conductive area 502 (compare 202). In this case, a horizontal isolation area 504c (compare 204c) extends completely across the top of the aluminum conductive area 502.

FIG. 6A illustrates a substrate 600 formed using ALOX™ technology, and is similar to FIG. 5. A vertical isolation area is shown having a one side portion 604a (compare 504a) and an opposite side portion 604b (compare 604b) surrounds (and defines) an aluminum conductive area 602 (compare 502). A first horizontal isolation area 604c (compare 504c) extends completely across the top of the aluminum conductive area 602. In this case, anodization is from both sides, and a second horizontal isolation area 604d extends completely across the bottom of the aluminum conductive area 602. The second horizontal isolation area 604d can be the same or a different thickness as the first horizontal isolation area 604c. This results in a buried slug 602 of aluminum. By shrinking the horizontal dimension of the vertical isolation area, the slug can be any desired width, such as shown by the slug 602′ in FIG. 6B in the substrate 600′ And, more complex interconnect structures are readily formed, as shown in FIG. 6C which has a slug 602″ (compare 602′) in a substrate 600″ which also has patterns of top metallization 606 (compare 206a, 206b) and bottom metallization 610 (compare 210). (In FIG. 6C, conductive materials are shown cross-hatched.)

### Embodiment 2

### Substrate with Cavities/Integrated Reflectors

As mentioned above, a consideration in LED packaging is directing the emitted light in a desired direction (usually, away from the substrate to which the LED is mounted). This is often achieved by mounting the LED die within a generally hemispherical cavity where the cavity walls act as a reflector. (Analogy, a halogen bulb in a car headlamp.) Typically the cavity is filled with a polymeric transparent material acting both as a lens and sealant material. Adding some additives to the molding material is sometimes used to shift or filter the emitted light to achieve a desired light wavelength for a particular application. A number of patents disclosing LED mounting techniques have been described hereinabove (in the background section). In general, the prior art is deficient because it requires an assembly of elements rather than the one integral body approach disclosed herein, and lacks the direct thermal path disclosed herein.

This embodiment is generally directed to various structural concepts which provide for a reflector and cavity along with the necessary routing traces incorporated in same ALOX™-based substrate.

A plurality of electronic components can be mounted and interconnected on an interconnect substrate. For example, a plurality of LEDs can be mounted in an array (regularly spaced, in rows and columns) and interconnected (in series, in parallel, in series-parallel combinations) with one another, or individually connected to the “outside world.”

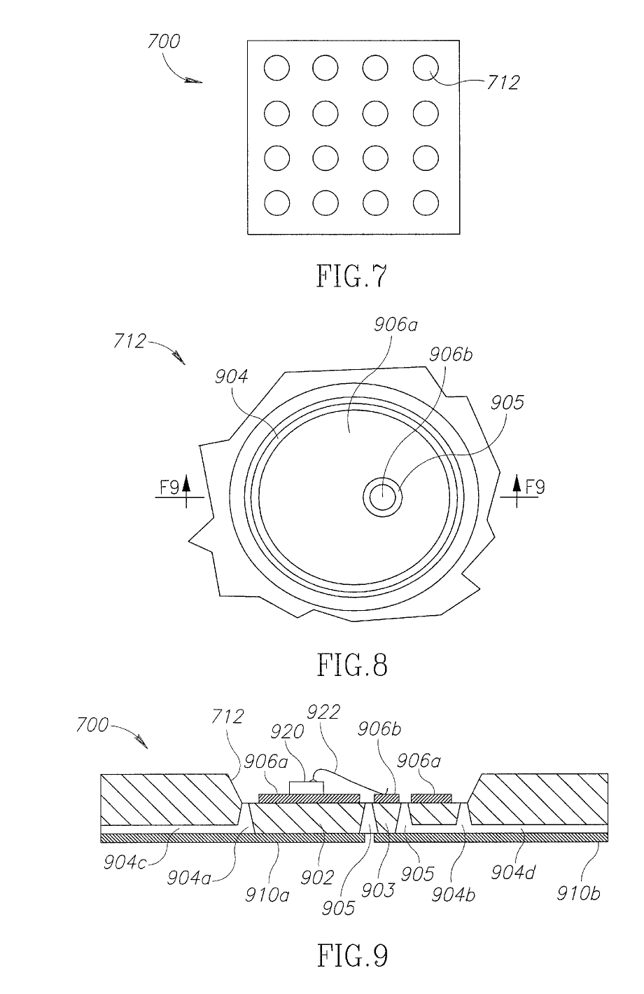

A second embodiment is shown and described with respect to FIGS. 7-16 using an example of assembling a plurality of LEDs assembled on an ALOX™-based substrate having cavities acting as reflectors. (And also having direct electrical/thermal metal connection between the electronic components and the bottom surface of the interconnect substrate, as in the embodiment of FIG. 2.)

FIG. 7 shows (top view) an ALOX™-based substrate 700 with a 4×4 array of cavities 712 for receiving a plurality (16) of LEDs (not shown).

FIG. 8 is a top view of a single cavity 712 of the substrate.

FIG. 9 shows, in cross-section, a single cavity 712 of the substrate 700.

The LED die 920 (compare 220) is mounted on a top metallization pad 906a (compare 206a) which is atop an electrically isolated area (region) of aluminum 902 (compare 202) which is defined by vertical isolation region (ring structure) 904a/904b (compare 204a/204b, see 904 in FIG. 8) to provide for the needed electrical isolation and the direct heat path from the die 920 to bottom of substrate 700. A first portion of bottom metallization 910a (compare 210) is disposed on the bottom of the substrate 700 and extends across the aluminum conductive region 902.

The LED 920 is bonded by a bond wire 922 (compare 222) to a metallization pad 906b (compare expanded portion of trace 206b) which is atop another conductive aluminum region (via) 903 formed by vertical isolation ring 905. A second portion of bottom metallization 910b (compare 210) is disposed on the bottom of the substrate 700 and extends to the via 903. In this embodiment, both connections to the LED are made via the bottom of the substrate.

To put things in perspective,
the substrate 700 is 300-500 μm thick;
the LED 720 measures approximately 1.2×1.2 mm.
the cavity 712 is about 0.7 mm wide at the top, about 0.6 mm wide at the bottom and 200-300 μm deep. The cavity is approximately half (30-70%) the thickness of the substrate.

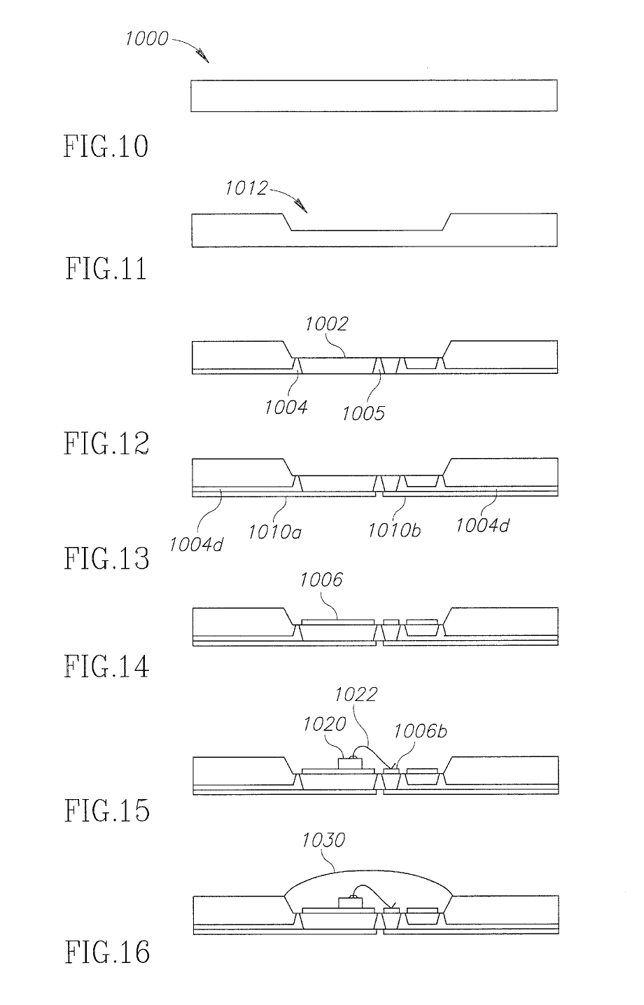

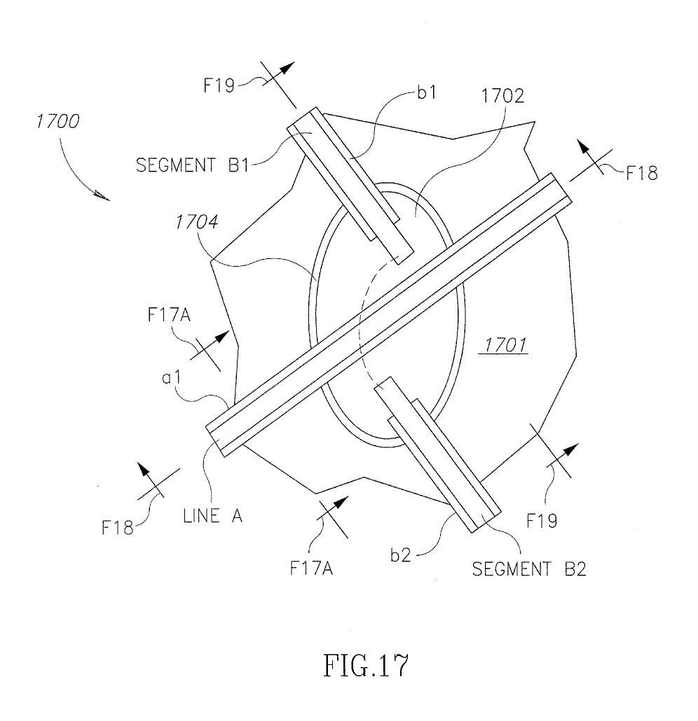

An exemplary process flow for forming interconnect substrates including integrated reflectors/cavities, using the ALOX™ process, is shown in FIGS. 10-16.

The starting material in the process flow is an aluminum substrate 1000 (FIG. 10). The substrate is in the form of a flat sheet, but it is within the scope of that, the substrate is not flat. For example, the substrate could be hemispherical.

The first step in the process is forming the cavity (recess) 1012. (FIG. 11). Cavity formation can be done employing various well-known techniques such as mechanical formation (drilling, punching, and the like), chemical etch formation or electro-chemical etching.

What is being illustrated here, is a “cavity first” embodiment. It should be understood that the cavity could be formed later in the process flow, as described hereinbelow.

A next step (FIG. 12) is the formation (by anodization) of vertical isolation rings 1004 and 1005 in the base of the cavity which create an aluminum electrical isolated area 1006a for the die attach and an aluminum via 1006b. The vertical isolation 1004 and 1005 is suitably formed using ALOX™ formation techniques described hereinabove. Horizontal isolation 1004c and 1004d is also formed in the bottom surface of the substrate, for electrically isolating conductive traces 1010a and 1010b (FIG. 13), respectively, from the substrate.

FIGS. 13 and 14 illustrate the bottom 1010 and top 1006 metallization process steps, respectively.

FIG. 15 illustrates assembly of the die 1020 to the substrate, and connecting it with a wire bond 1022 to top metallization pad 1006b.

FIG. 16 illustrates capping the die 1020 with molding/lens material 1030. The cavity 1012 is filled with a polymeric transparent material acting both as a lens and sealant material. The material 1030 encapsulates the die 1020 (and the bond wire).

The cavity can be formed as late as after metallization (FIG. 14) and before component mounting (FIG. 15).

Electrochemical polishing can be utilized to give the cavity a bright, reflective surface. This can be incorporated in (aligned with) the cavity forming phase (FIG. 11).

It should be understood that various process schemes similar to the above described process flow can be used to achieve same or similar structural results. One example for such variation in process flow is to start with the anodization steps to form the rings (and horizontal isolation) isolating aluminum areas followed by cavity formation (“cavity last”) using a mechanical or other suitable method. Preferably, cavity formation should be done before the metallization steps (and certainly before die mounting/bonding and molding/capping).

### Thinning to Allow for One-Sided Deep Anodization

The ALOX™ technology utilizes deep anodization for creation of the vertical isolation areas. Deep anodization is generally limited to a depth of about a maximum of 300-600 μm for two-sided anodization and to about 150-300 μm for one-sided anodization. In the example above, cavities are formed for the purpose of functioning as reflectors for LEDs mounted on the substrate, and one-sided anodization was used. Cavities, or recesses, can also be used to facilitate formation of vertical isolation structures in substrates that are too thick for one sided anodization, as discussed in greater detail hereinbelow.

Generally, a “thick substrate”, such as a substrate having a thickness in excess of 500 or 600 μm, including over 1 mm, is thinned (by etching, or mechanically) to less than 500 or 600 μm in selected areas whereat is it desired to perform anodization completely through the substrate, to form electrically isolated conductive areas. For one-sided anodization, it would be desirable to locally thin the substrate to less than 200 or 300 μm.

In other words, an interconnect substrate can be formed by starting with a valve metal (for example, aluminum) substrate, thinning the substrate in selected areas whereat it is desired to form isolated conductive areas, then anodizing the substrate to form electrically isolated conductive areas in the thinned areas. The anodization may performed from only one side of the substrate, or the anodization may be performed from both sides of the substrate.

### Embodiment 3

### Electrical Traces Crossing Each Other (“Cross-Overs”)

In multilayer structures there is often a need to route the electrical traces in such a way that one line is crossing (crosses over) another line and the two lines should be electrically isolated from one another. In almost all cases this is solved employing two separate (metallization) layers incorporating the conductive traces (metal layers) that are isolated from one another by a dielectric layer. This is usually the solution employed in PWB boards, in ceramic boards and in silicon wafers incorporating ICs circuitry.

A technique is provided for implementing cross-overs using ALOX™ technology, with only one metallization layer (level).

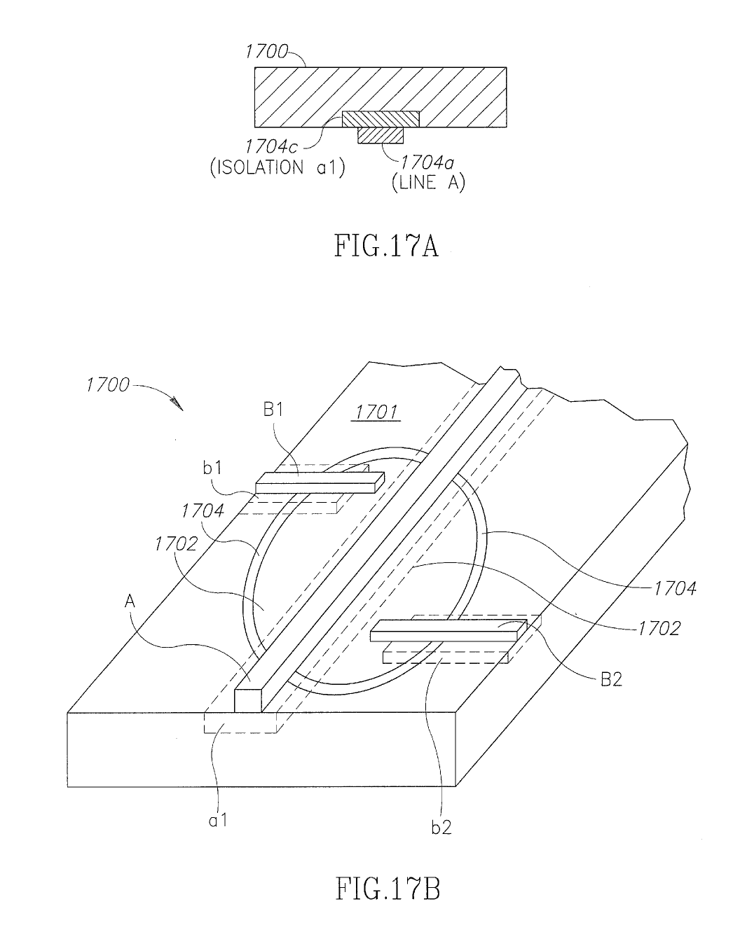

This embodiment is shown and described with respect to FIGS. 17-24. This is shown utilizing a substrate having a recess (or cavity, as in the previous embodiment).

Generally, this embodiment is based on using the aluminum core material as an electrical bridge, isolated from the metal layer containing both lines crossing each other, as described in greater detail hereinbelow.

FIG. 17 is bottom view of a substrate 1700. The substrate may have a cavity 1712 as shown in FIG. 17 but can also be flat substrate having no cavities. A vertical isolation ring (structure) 1704 (compare 204) defines an isolated aluminum crossing area 1702 (compare 202), within the cavity 1712. The crossing area extends through the substrate from a surface thereof to the opposite surface thereof.

Two conductive traces “A” and “B” are shown, crossing one another in the crossing area 1702. The trace A is a continuous (uninterrupted, unsegmented) line. The trace B is segmented, having two segments B1 and B2, the ends of which are spaced apart from one another to allow the trace A to pass through a space between the spaced-apart ends of the segments B1 and B2. The traces A and B are substantially coplanar, on the (bottom 1701) surface of the substrate 1700. A dashed line schematically illustrates that the two conductive trace segments B1 and B2 are electrically connected with one another.

Generally each of the conductive traces A and B is disposed on a corresponding previously formed anodized horizontal isolation area (or region) so that it is electrically isolated from the substrate. The horizontal isolation is similar to how 206b is laying on 204c in FIG. 2, but in this case the horizontal isolation area is not extending from a vertical isolation area. The conductive traces A and B are formed from a single layer of metallization, and are substantially coplanar with one another.

FIG. 17A shows a detail of one of the horizontal isolation areas. The horizontal isolation area 1704c (compare 910c) extends into the bottom surface of the substrate 1700, forming a “bed” of isolation upon which the conductive trace 1710a (compare 910a) can be formed. (Analogy. A bed of crushed stone upon which a railway track is laid.) Generally, both the horizontal isolation area and the conductive trace formed on the horizontal isolation area are typically (not necessarily) elongate. The horizontal isolation area extends only partially into the substrate. Thus, with respect to the horizontal isolation area, the thickness of the substrate is somewhat immaterial. Typical dimensions may be:
width of the horizontal isolation area: 200 um or 25 to 500 um.
width of the conductive trace: 100 um or 10 to 450 um.

The important thing is that the horizontal isolation area is wider than the conductive trace to ensure that the conductive trace is electrically isolated from the substrate.

Before forming the conductive trace (analogy, railroad track) “A”, a horizontal isolation area (analogy, “bed”) is formed on the surface of the substrate. Then, the conductive trace A is formed on the isolation area. In this example, the isolation area “a1” traverses completely across the crossing area 1702, and the conductive trace A traverses completely across the crossing area 1702. Therefore the conductive trace A is electrically isolated from the crossing area 1702 even though it crosses directly over it. (The isolation area a1 is disposed between the conductive trace A and the crossing area 1702.)

Before forming the conductive trace segments B1 and B2, two horizontal isolation areas “b1” and “b2” (for example, in the form of linear segments, circular segments or other trace paths), having a width which is greater than the width of the respective conductive trace segments under which they are formed on the surface of the substrate. According to some embodiments, the horizontal isolation areas b1 and b2 extend onto the crossing area 1702, and their ends are disposed on the crossing area and are separated from one another.

According to other embodiments, the conductive trace segment B1 extends beyond the end of the horizontal isolation area b1 upon which it is formed, onto the aluminum crossing area 1702, and is thus electrically connected to the aluminum core crossing area 1702. The conductive trace segment B2 extends beyond the end of the horizontal isolation area b2 upon which it is formed, onto the aluminum crossing area 1702, and is thus electrically connected to the crossing area 1702. In this manner, the aluminum core crossing area 1702 electrically connects (bridges, as indicated by the dashed line) the two conductive trace segments B1 and B2 without shorting to conductive trace A. A cross-over has been effected. It is within the scope of this disclosure that an additional conductive trace segment (for example, “B3”) could extend onto the crossing area and be connected with the other two conductive trace segments B1 and B2.

As illustrated in FIG. 17, the conductive trace line A passes through the separation between the ends of the conductive line segments B1 and B2, which means that the conductive line segments B1 and B2 must be spaced sufficiently apart from one another that the line A can pass therethrough without shorting to the line segments B1 and B2.

The isolation areas a1, b1 and b2 can be formed as one big complex shape horizontal isolation area, the important thing being that there is “exposed” crossing area to make the connection between the two line segments B1 and B2. In other words, most of the crossing area could be anodized, as long as there are two exposed areas for effecting the desired connection.

In this example (FIG. 17), the two conductive trace segments B1 and B2 are not co-linear, but are laid along different lines (in kind of a “broken” line structure). This is not a critical aspect of this embodiment, but merely illustrates the flexibility of the process. Also, the elliptical shape of the crossing area 1702 is not critical. It may be virtually any shape, the important thing being that it is electrically isolated from the remainder of the substrate. In this example, one cross-over per cavity is illustrated. Two or more cross-overs per cavity could be implemented using the same technique.

An analogy. You have a wooden (electrical insulator) table (the “substrate”). A flat metal (electrical conductor) plate (“crossing area”) sitting on the table. A first insulated wire (the line A) extends across the metal plate. Another insulated wire (B) is laid across the first insulated wire (A), but first it is cut into two pieces, the ends of the wires are separated from one another and stripped (exposing the inner wire conductor), and the ends of the two pieces of wire (B1 and B2) make contact with one another through the flat metal plate. Wires A and B are in the same plane (on the surface of the plate), but they need not actually physically cross on another.

FIG. 17B presents a three-dimensional view of the substrate 1700 and the locations of the trace A and the isolation area a1 with respect to the segments B1 and B2 and the isolation areas b1 and b2.

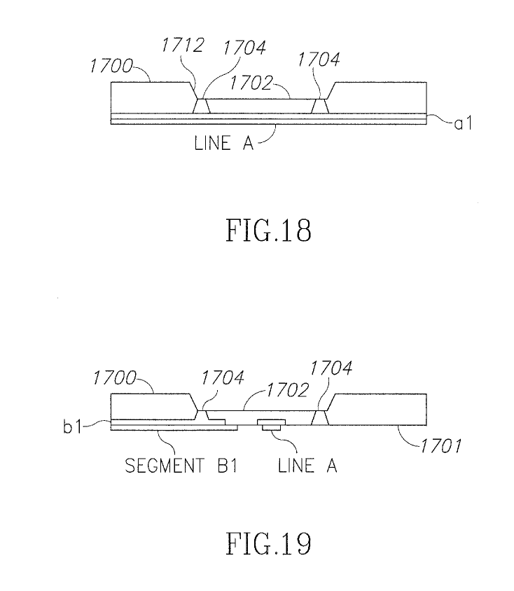

FIGS. 18 and 19 are cross-sectional views through the substrate of FIG. 17.

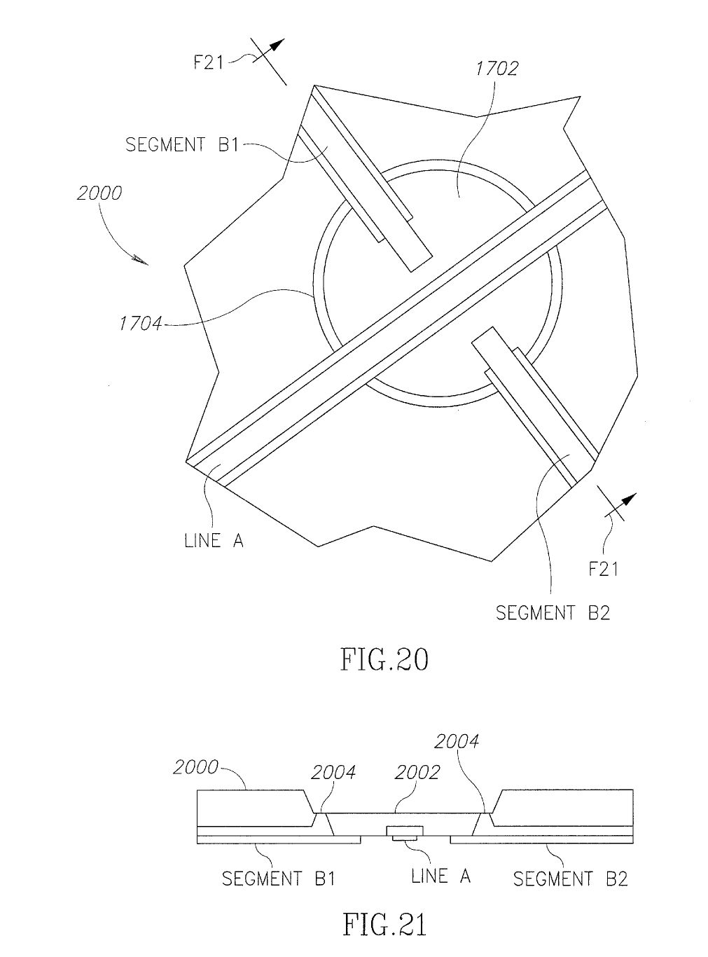

FIGS. 20 and 21 illustrate a substrate 2000 (compare 1700) having similar crossing structure. In this version, the two conductive trace segments B1 and B2 are collinear, and the crossing area 2002 (compare 1702) formed by the vertical isolation 2004 (compare 1704) has a generally circular rather than elliptical shape.

The process flow for forming the cross-overs is similar to the process flow described hereinabove with respect to FIGS. 10-16.

The “in plane” (one layer) crossing-over technique disclosed herein is very useful in applications where only a few crossing zones are required, because the crossing-over area is not a very efficient use of real estate. However, employing the technique disclosed herein has the advantage of eliminating the need for an additional routing metal layer (separated by a dielectric layer) for crossing lines. Only one routing metal layer is required to build the substrate and achieve the required connectivity. This simplifies the structure and lowers the cost of the final substrate and package structure.

### Embodiment 4

### Combination of Cavity and Cross-Over

This embodiment illustrates combing the previous two embodiments (that is, incorporating the crossing area of two (or more) lines within (opposite) a cavity area acting as reflector/housing area for a device such as an LED). Such a combination allows for lower process cost and also area savings on board because with this configuration there is no need to allocate special area on the board for the crossing area separate from the cavity/reflector area. In other words, whether thinning is needed or not (for one side anodization), a single area of the substrate can be used for LED mounting (on one side) and for effecting simple cross-overs (on the other side).

FIGS. 22 and 23 are top and bottom views, respectively, of an embodiment of a substrate, according to another embodiment of the interconnect substrate of the disclosure.

FIG. 24 is a cross-sectional view taken through either of FIG. 22 or 23.

This embodiment is similar to the previous embodiments in that is has a substrate 2200 (compare 1700) with a cavity 2212 (compare 1712) and a vertical isolation area 2204 (compare 1704) defining an aluminum crossover area 2202 (compare 1702).

In this embodiment, there is an additional vertical isolation ring 2205 located within the conductive crossover area 2702 and defining a distinct metal via 2203 extending through the substrate in the cavity area 2712 to effect a connection from a conductive line 2206b on the top surface of the substrate to a conductive line 2210b on the bottom surface of the substrate.

### Embodiment 5

### Two (or More) Devices Assembled on “Thick” Aluminum Substrate

In some cases devices (electronic components) can be assembled and connected on a common metal base in a parallel mode. For example, two diodes having their cathodes (or anodes) connected with one another. This embodiment assumes that no dense routing scheme is required, and that only one metal routing layer is sufficient.

This embodiment also assumes (illustrates an example of a situation) that there is no need for electrical vias (for example, 202) extending through the substrate, and that no vertical isolation (anodization through the substrate) between devices is needed. Therefore, the substrate can generally be thicker than in the previous embodiments. For descriptive purposes, the term “heavy” or “thick” is used herein for aluminum substrates having a thickness greater than approximately 0.5-0.6 mm, reaching in some cases thickness in the millimeters range.

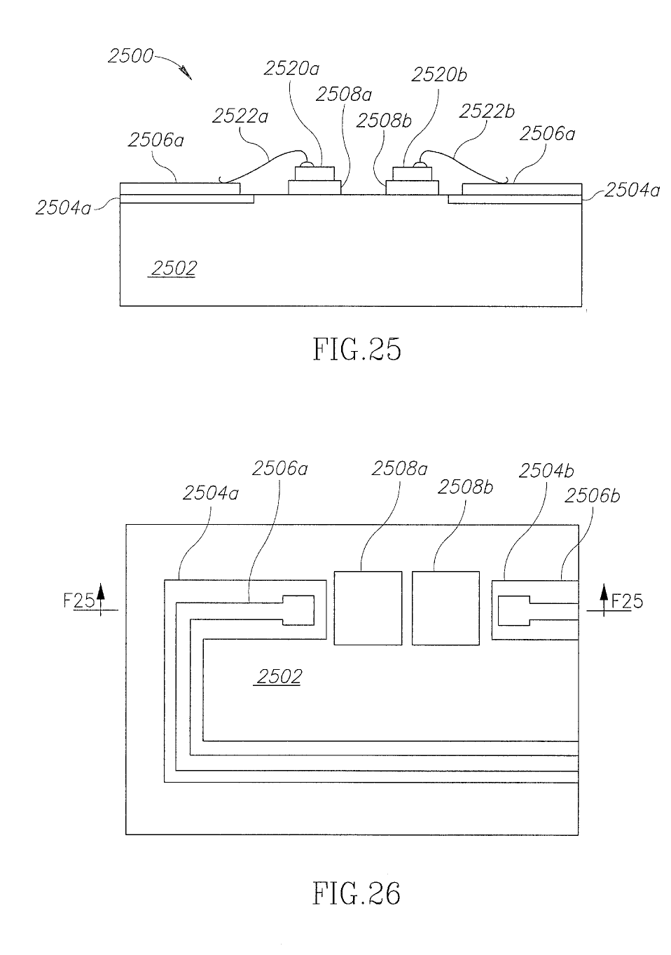

FIG. 25 is a cross-sectional view of an interconnect substrate 2500 comprising:
an aluminum (valve metal) sheet 2802,
two local ALOX™ isolation areas 2504a and 2504b (compare 1704c)
conductive traces 2506a and 2506b (compare 206b, 1704a) formed on the local ALOX isolation areas, and
pads 2508a and 2508b for attachment of devices 2520a and 2520b (compare 220).

The two local isolation areas 2504a and 2504b extend into the substrate 2502 from a surface thereof, and extend along the surface of the substrate. The conductive traces 2506a and 2506b are disposed upon extend along respective ones of the two local isolation areas 2504a and 2504b. (compare the lines and line segments in FIG. 17)

The devices (electronic components) 2520a and 2520b are mounted on the pads 2508a and 2508b, and are connected with wire bonds 2522a and 2522b (compare 222) to the conductive traces 2506a and 2506b, respectively. The two pads 2508a and 2508b are shown as being disposed directly on the substrate 2502, both in contact with (having one terminal connected to) the aluminum body of the substrate 2502. The aluminum body of the substrate 2502 could be, for example, ground.

FIG. 26 is a top view of the substrate of FIG. 25.

### Embodiment 6

### Cavity Isolation on Thick ALOX™ Substrate

The term “thick” or “heavy” is used herein for aluminum substrates of over around 0.5-0.6mm (500-600 μm), reaching in some cases thickness in the millimeters range. In some cases it is desired to use a thick (heavy) aluminum substrate as base for the structure as described hereinabove (for example, in FIGS. 2, 3 4, or FIGS. 8, 9) employing vertical isolation (through anodization). In these cases, whether with a cavity (for example, FIG. 8) or without a cavity (for example, FIG. 2), the thickness of the substrate in the area that (for example, 202, 902) that needs to be vertically isolated is simply too thick for forming vertical isolation, whether by one-sided or two-sided anodization.

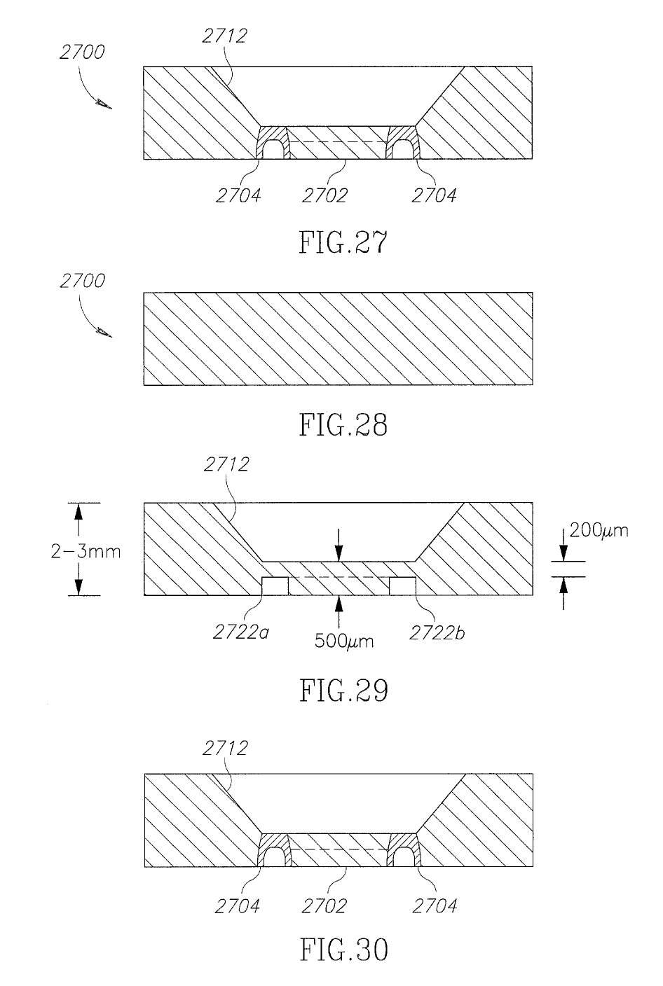

FIG. 27 is a cross-sectional view of an interconnect substrate 2700, according to an embodiment of the interconnect substrate of the disclosure.

This embodiment illustrates a situation where there is a cavity 2712 formed on the top (front) surface of a thick ALOX™ substrate, and vertical isolation is needed. (compare FIG. 9). Only a cross-section is shown, but it will be understood that the cavity can have various shapes (typically circular). An exemplary overall thickness of the substrate, outside of the cavity area may be 2-3 mm.

In a previously-described embodiment, there was a cavity (for example, 712) on the front (top) side of a thick substrate for receiving an LED. It has also been discussed that cavities, or recesses, can also be used to facilitate formation of vertical isolation structures in substrates that are too thick for one sided anodization.

In this embodiment, the substrate is too thick for one-sided through anodization, even at the bottom of the cavity 2712 where the substrate is substantially thinned.

The gist of this embodiment is to provide local recesses to locally reduce the thickness of the “remaining aluminum thickness” at strategic locations on the bottom (back) side of the substrate, which is the side from which anodization proceeds. (However, it is within the scope of the this embodiment that the local recesses could be provided on the other, top/front side, or cavity side of the substrate.).

In the figures, two local recesses 2722a and 2722b are shown extending into the substrate from the back side of the substrate, under the cavity area 2712 where the substrate is already thinned. For example, the thickness of the substrate at the cavity bottom is 500 μm, the recesses are 300 μm deep, leaving 200 μm of material between the bottoms (top, as viewed) of the recesses and the bottom surface of the cavity 2712. This is best viewed in FIG. 29.

The local recesses allows for an ALOX™ vertical isolation structure to be formed in (and through) the substrate, in the recess zone (substrate area surrounding each recess). The recess zone is converted to ALOX material, which also partially fills the recesses. Optionally, any remaining recess can be filled with some polymeric molding or capping material (not shown) to achieve a flat back surface for the substrate as may be desired by the designer.

In U.S. Pat. No. 6,448,510, a pin jig fixture is disclosed for mechanically masking a metal surface, the pin jig fixture having an anodization resistant bed of pins each pin having a leading end surface for intimate juxtaposition against the surface of the substrate to mask portions thereof and prevent anodization (resulting in isolated conductive areas). Essentially, one pin per via.

Here we have an example of controlling where anodization can proceed completely through the substrate, by local thinning of the substrate (as also mentioned hereinabove). Rather than using a pin-jig fixture to control where anodization occurs, selective thinning (recesses) of the substrate can be used to control where anodization can proceed through the substrate, and all other areas will be only partially anodized (not completely through the substrate.

FIGS. 27-30 are cross-sectional views. The two recesses 2722a and 2722b may be two opposite sides of a ring groove extending in the surface of the substrate. (Analogy, an O-ring groove.) In which case, the recesses would form a vertical isolation ring 2704 surrounding and electrically isolating an aluminum conductive area 2702 from the remainder of the substrate.

The two recesses 2722a and 2722b may be two parallel lines extending into the page (as viewed), never to intersect. Analogy, two linear grooves extending along a surface of a substrate.

The two recesses 2722a and 2722b can be two of many individual recesses, for example disposed in an array of appropriately spaced-apart recesses (up to 0.4 or 0.5 mm apart from one another), perforating a surface of a substrate so that ALOX™ material may be formed over a large area of a substrate, spanning between adjacent recesses, and extending deeper into the substrate as determined by the depth of the recesses (blind holes), whether only partially through the substrate or fully through the substrate, depending on the design requirement.

In most cases contemplated by this embodiment, the recesses extend only partially through the substrate, but they could extend fully through the substrate.

FIGS. 28-30 show processes flow for building cavity isolation on thick ALOX substrate: FIG. 28 is showing the bare thick aluminum used, FIG. 29 shows formation of the cavity and recess at the back for the vertical isolation and FIG. 30 is showing the structure post formation of the ALOX isolation. This process flow is an example and variations can be employed such as formation of the top cavity separately at end of process, and such other variations as may be apparent to people skilled in the art.

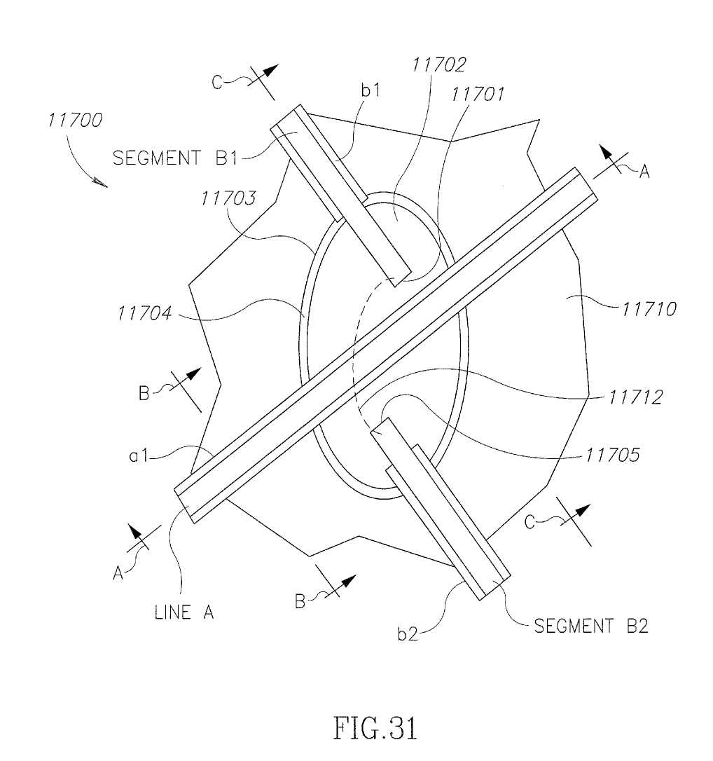

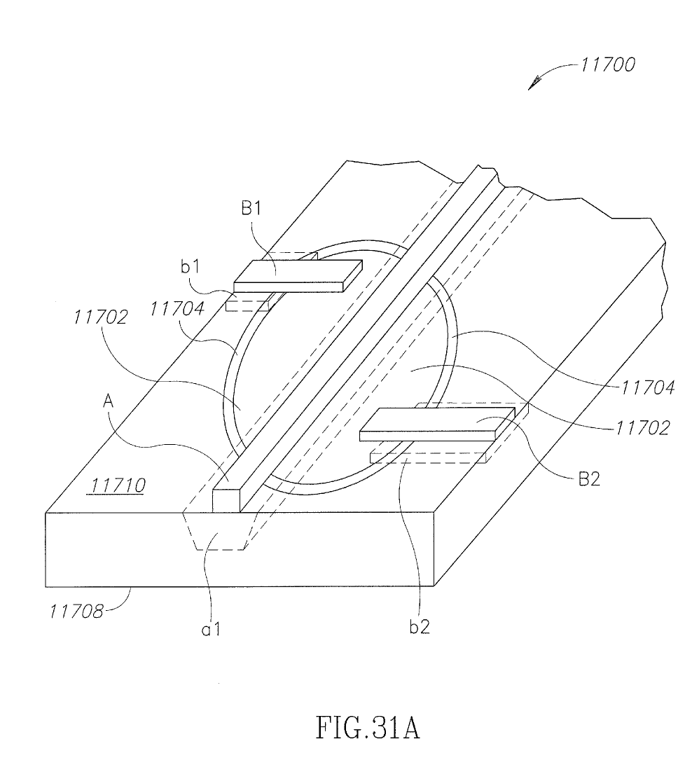

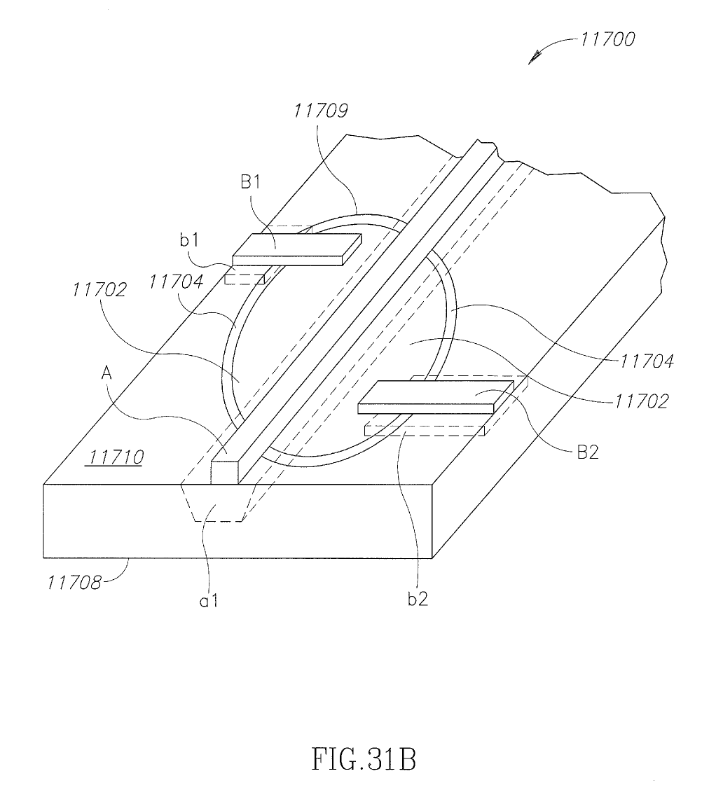

Reference is now made to FIG. 31, which shows a view of a substrate 11700, in accordance with another preferred embodiment of the present invention. A vertical isolation closed structure 11704 encompasses an isolated crossing area 11702. Crossing area 11702 extends through substrate 11700 from an upper surface 11708 (not shown) to a lower surface 11710 (shown in FIG. 31A) of substrate 11700.

A continuous and unsegmented conductive trace “A” and a segmented conductive trace “B” are formed the lower surface 11710 of the substrate 11700. The trace A and the segmented trace B are typically coplanar. The segmented conductive trace B includes at least two segments “B1” and “B2”, which are separated by the trace A, as shown in FIG. 31. The conductive traces B1 and B2 extend into the crossing area 11702.

The conductive trace A is formed on an isolation area “a1”, and the conductive trace segment B1 and the conductive trace segment B2 are formed on isolation areas “b1” and “b2”, respectively. It is appreciated that the isolation area a1 is wider than the trace A1 and that the isolation areas b1 and b2 are wider than the traces B1 and B2, respectively, thereby ensuring that the conductive traces A, B1 and B2 are electrically isolated from the substrate 11700.

It is further appreciated that the trace A is sufficiently disposed from terminal ends 11701 and 11705 of segments B1 and B2, respectively, such that line A traverses between the segments B1 and B2 without electrically shorting to the line segments B1 and B2. As shown in FIG. 31, the conductive trace line A passes between the separated trace segments B1 and B2 and thus the conductive trace A is electrically isolated from the conductive traces B1 and B2. A dashed line 11712 schematically shows that the at least two conductive trace segments B1 and B2 are electrically connected.

FIG. 31 shows that the isolation area b1 extends to the outer periphery 11703 of the isolation structure 11704 and does not protrude into the crossing area 11702. As shown in FIG. 31, isolation area b1 extends onto isolation structure 11704 and does not protrude into the crossing area 11702, while isolation area b2 extends through isolation structure 11704 and into the crossing area 11702.

Typically, the conductive traces A and B are disposed on corresponding formed anodized horizontal isolation structures, such that the conductive traces A, B1 and B2 are electrically isolated from the substrate 11700. In addition, according to some embodiments, the conductive traces A, B1 and B2 are formed from a single layer of metallization, and are substantially coplanar with each other.

Reference is now made to FIG. 31A, which presents a three-dimensional view of the substrate 11700 of FIG. 31, in accordance with some embodiment s of the present invention. FIG. 31A shows the locations of the trace A and the isolation area a1 with respect to the segments B1 and B2 and the isolation areas b1 and b2.

Reference is now made to FIG. 31B, which presents a three-dimensional view of the substrate 11700, in accordance with anther embodiment of the present invention. FIG. 31B shows the locations of the trace A and the isolation area a1 with respect to the segments B1 and B2 and the isolation areas b1 and b2. It is shown in FIG. 31B that the isolation area b1 terminates at an outer periphery 11709 of the isolation structure 11704. According to this embodiment solation area b1 connects to isolation structure 11704 but does not continue into isolation structure 11704.

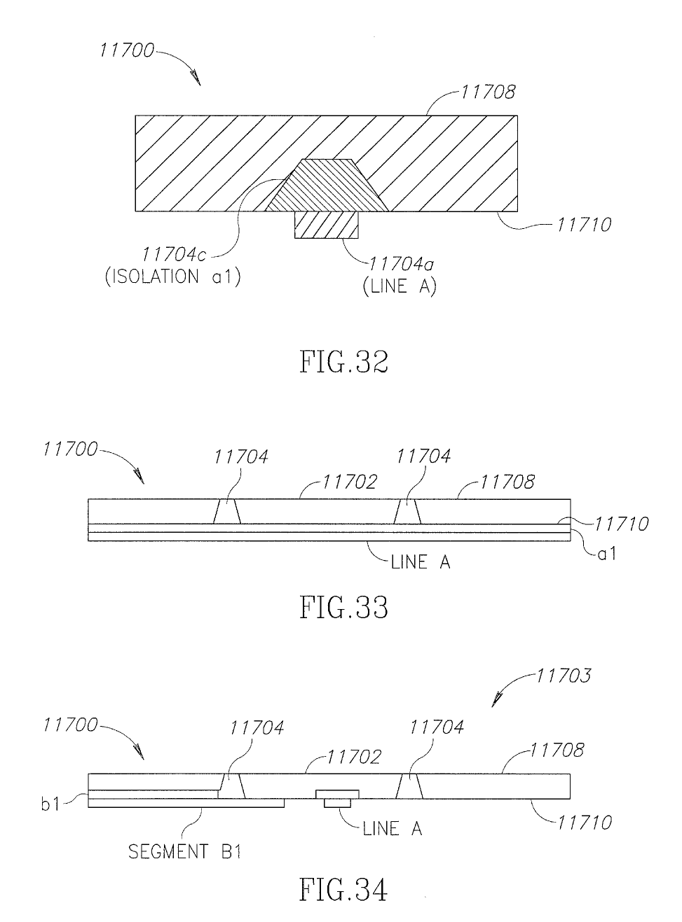

Reference is now made to FIG. 32, which shows a vertical cross-sectional portion of the substrate 11700 in the direction of the arrows B-B in FIG. 31, in accordance with another preferred embodiment of the present invention. FIG. 32 shows a vertical cross-sectional portion of the substrate 11700, including an isolation area 11704c (“a1”). The isolation area 11704c is formed on the lower surface 11710 of the substrate 11700 and extends into the substrate 11700. The isolation area a1 forms an isolation base upon which the conductive trace 11710a (“Trace A”) is formed.

In FIG. 32, the isolation structure 11704c is shown to have a trapezoidal cross-sectional area. It is appreciated that the structure 11704c can have alternative cross-sectional geometries, such as a rectangular cross-sectional area, a square cross-sectional area, a circular cross-sectional area, an ellipsoidal cross-sectional area or a polygonal cross-sectional area and/or any combination thereof.

Reference is now made to FIG. 33, which presents a vertical cross-section of the substrate 11700 in the direction of arrows A-A in FIG. 31, in accordance with another preferred embodiment of the present invention. FIG. 33 shows the location of the trace A and isolation area a1 with respect to the lower trace 11710 of the substrate 11700. FIG. 33 also shows that the trace A and the isolation area a1 extend along the lower surface 11710 of the substrate 11700. It is noted that unlike substrate 1700 shown in FIGS. 17-19, in substrate 11700 of FIG. 33 the crossover area 11702 is not within a cavity.

Reference is now made to FIG. 34, which presents a vertical cross-section of the substrate 11700 in the direction of arrows C-C in FIG. 31, in accordance with another preferred embodiment of the present invention. FIG. 34 shows the location of the segment B1 and isolation area b1 relative to the upper trace 11708 and the lower trace 11710 of the substrate 11700. FIG. 34 also shows that the segment B1 extends beyond the isolation structure 11704 and is in contact with the crossing area 11702. In addition, FIG. 34 shows that the segment B1 terminates at the outer periphery 11703 of the isolation structure 11704.

Also shown in FIG. 34 is that the width of the isolation structure varies from the top to bottom surfaces, in other embodiments, the shape of the isolation structure may vary between the top and bottom surface, while remaining continuous and defining an isolation region spanning the thickness of the substrate.

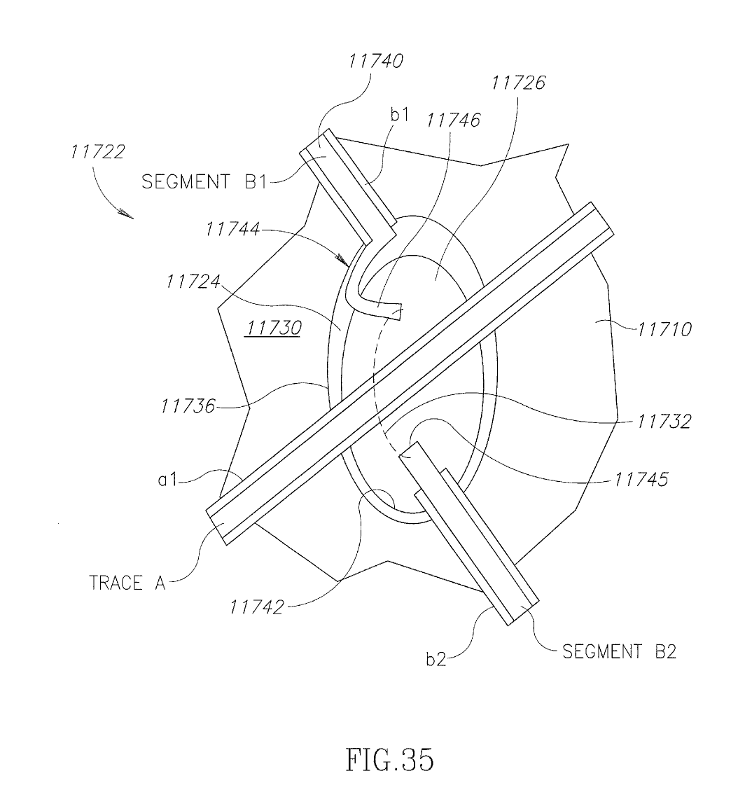

Reference is now made to FIG. 35, which shows a view of a substrate 11722, in accordance with another preferred embodiment of the present invention. A vertical isolation closed structure 11724 encompasses an isolated crossing area 11726. Crossing area 11726 extends through substrate 11722 from an upper surface 11728 (not shown) to a lower surface 11730 of substrate 11722.

A continuous and unsegmented conductive trace “A” and a segmented conductive trace “B” are formed the lower surface 11730 of the substrate 11722. The trace A and the segmented trace B are typically coplanar. The segmented conductive trace B includes at least two segments “B1” and “B2”, which are separated by the trace A. The conductive traces B1 and B2 extend into the crossing area 11726.

The conductive trace A is formed on an isolation area “a1”, and the conductive trace segment B1 and the conductive trace segment B2 are formed on isolation area “b1” and “b2”, respectively. It is appreciated that the isolation area a1 is wider than the trace A1 and that the isolation areas b1 and b2 are wider than the traces B1 and B2, respectively, thereby ensuring that the conductive traces A, B1 and B2 are electrically isolated from the substrate 11722.

It is further appreciated that the trace A is sufficiently disposed from terminal ends 11746 and 11745 of segments B1 and B2, respectively, such that line A traverses between the segments B1 and B2 without electrically shorting to the line segments B1 and B2. FIG. 35 shows that the conductive trace line A passes between the separated trace segments B1 and B2 and thus the conductive trace A is electrically isolated from the conductive traces B1 and B2. A dashed line 11732 schematically shows that the at least two conductive trace segments B1 and B2 are electrically connected.

The isolation area b1 connects to isolation portion 11724 and does not protrude into the crossing area 11726.

A metallization trace 11740 (B1) is formed on the isolation area bland extends to at least a portion of the isolation structure 11724 and on to crossing area 11726. Metallization trace 11740 is a continuous trace and does not reach the peripheries of isolation structure 11724, in order to prevent an electrical short.

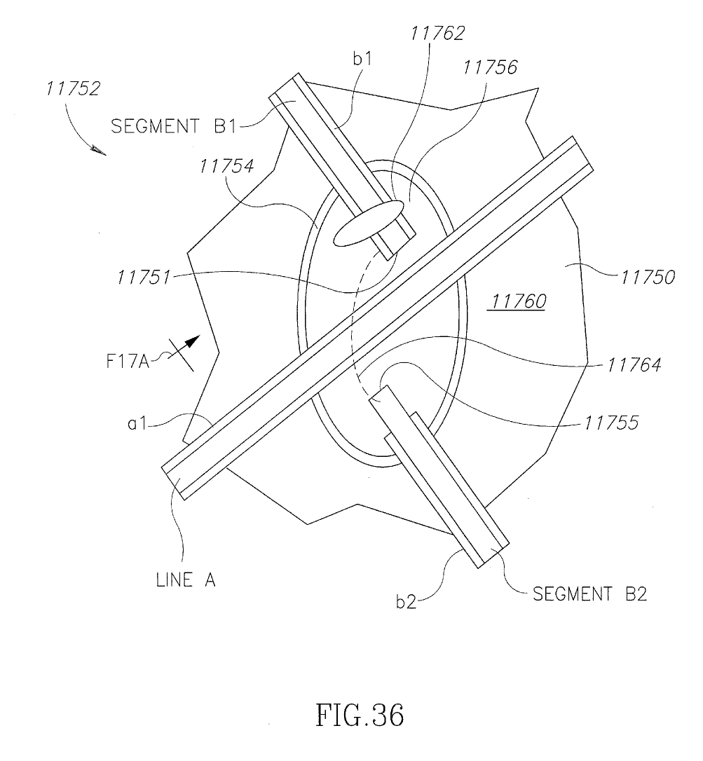

Reference is now made to FIG. 36, which shows a view of a substrate 11752, in accordance with another preferred embodiment of the present invention. A vertical isolation closed structure 11754 encompasses an isolated crossing area 11756. Crossing area 11756 extends through substrate 11752 from an upper surface 11758 (not shown) to a lower surface 11760 of substrate 11752.

A continuous and unsegmented conductive trace “A” and a segmented conductive trace “B” are formed the lower surface 11760 of the substrate 11752. The trace A and the segmented trace B are typically coplanar. The segmented conductive trace B includes at least two segments “B1” and “B2”, which are separated by the trace A. The conductive traces B1 and B2 extend into the crossing area 11756.

The conductive trace A is formed on an isolation traces“a1”, and the conductive trace segment B1 and the conductive trace segment B2 are formed on isolation areas “b1” and “b2”, respectively. It is appreciated that the isolation area a1 is wider than the trace A1 and that the isolation areas b1 and b2 are wider than the traces B1 and B2, respectively, thereby ensuring that the conductive traces A, B1 and B2 are electrically isolated from the substrate 11752.

It is further appreciated that the trace A is sufficiently disposed from terminal ends 11751 and 11755 of segments B1 and B2, respectively, such that line A traverses between the segments B1 and B2 without electrically shorting to the line segments B1 and B2. FIG. 36 shows that the conductive trace line A passes between the separated trace segments B1 and B2 and thus the conductive trace A is electrically isolated from the conductive traces B1 and B2. A dashed line 11764 schematically shows that the at least two conductive trace segments B1 and B2 are electrically connected.

The segment B1 and the isolation area b1 are substantially of equal length and the segment B1 and the isolation area b1 extend into the crossing area 11756. In addition, the segment B2 extends beyond the edge of the isolation area b2 and the segment B2 and the isolation area b2 protrude into the crossing area 11756.

In previous embodiments disclosed hereinabove, isolation area b1 extends onto the crossing area, and that conductive trace B1 extends linearly, beyond isolation area b1, onto the crossing area. In this embodiment, a portion of segment B1, which is referred to as “portion 11762”, laterally extends onto crossing area 11756. In other words, the conductive traces, such as conductive trace B1, do not necessarily extend linearly along their respective isolation areas (such as isolation area b1) but in fact, can cross the crossing area (such as crossing area 11756) at any point. This configuration enables a smaller overall, crossover system, as well as an increased conduction region.

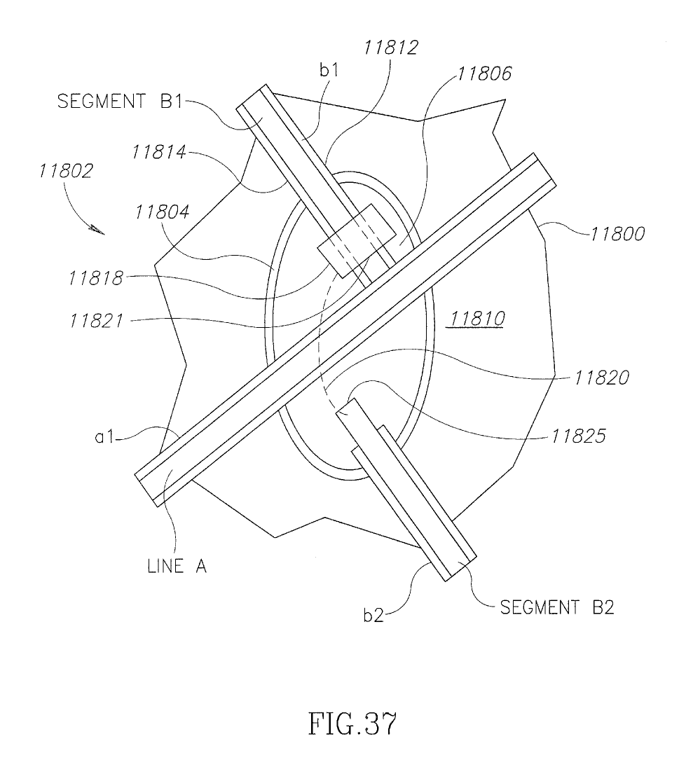

Reference is now made to FIG. 37, which shows a view of a substrate 11802, in accordance with another preferred embodiment of the present invention. A vertical isolation closed structure 11804 encompasses an isolated crossing area 11806. Crossing area 11806 extends through substrate 11752 from an upper surface 11808 (not shown) to a lower surface 11810 of substrate 11802.

A continuous and unsegmented conductive trace “A” and a segmented conductive trace “B” are formed the lower surface 11810 of the substrate 11802. The trace A and the segmented trace B are typically coplanar. The segmented conductive trace B includes at least two segments “B1” and “B2”, which are separated by the trace A. The conductive traces B1 and B2 are traverse to each other within the crossing area 11806.

The conductive trace A is formed on an isolation structure “a1”, and the conductive trace segment B1 and the conductive trace segment B2 are formed on isolation areas “b1” and “b2”, respectively. It is further appreciated that the isolation area a1 is wider than the trace A1 and that the isolation areas b1 and b2 are wider than the traces B1 and B2, respectively, thereby ensuring that the conductive traces A, B1 and B2 are electrically isolated from the substrate 11802.

In FIG. 37, at least one portion 11818 of the segment B1 extends beyond outer peripheries 11812 and 11814 of the isolation area b1 and the at least one portion 11818 protrudes into the crossing area 11806, forming a conduction region and thereby increasing electrical contact surface with the crossing area 11806. Isolation area b1 abuts the isolation area a1, thereby simplifying the deposition of the isolation area as well as increasing reliability of the device. In addition, by making the traces continuous, they are likely to be less prone to end effects.

It is appreciated that the trace A is sufficiently disposed from terminal ends 11821 and 11825 of segments B1 and B2, respectively, such that line A traverses between the segments B1 and B2 without electrically shorting to the line segments B1 and B2. FIG. 37 shows that the conductive trace line A passes between the separated trace segments B1 and B2 and thus the conductive trace A is electrically isolated from the conductive segments B1 and B2. A dashed line 11820 schematically shows that the at least one portion 11818 and the segment B2 are electrically connected.

In addition, in FIG. 37, the conductive trace line A traverses the separated trace segments B1 and B2 and the conductive trace A is electrically isolated from the conductive segments B1 and B2.

The segment B2 extends beyond the isolation area b2, and the segment B2 and the isolation area b2 protrude into the crossing area 11806.

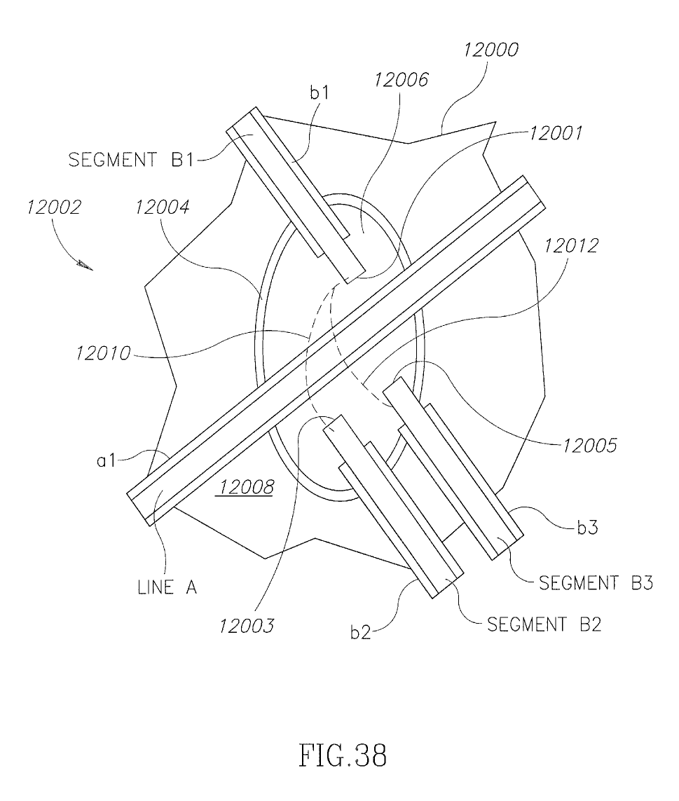

Reference is now made to FIG. 38, which shows a view of a substrate 12002, in accordance with another preferred embodiment of the present invention. A vertical isolation closed structure 12004 encompasses an isolated crossing area 12006. Crossing area 12006 extends through substrate 12002 from an upper surface 12007 (not shown) to a lower surface 12008 of substrate 12002.

A continuous and unsegmented conductive trace “A” and a segmented conductive traces B is formed the lower surface 12008 of the substrate 12002. The trace A and the segmented trace B are typically coplanar. The segmented conductive trace B includes a plurality of segments B_{i,i=1 . . . N} located at various positions on the lower surface 12008, thus substrate 12002 can function as a reliable junction for multiple trace B segments. Using such crossover design, multiple B segments can be connected reliably and cost effectively.

FIG. 38 shows three segments “B1”, “B2” and B3, N=3, formed on the substrate 12002. The segment B1 and the segments B2 and B3 are separated by the trace A and the segments B2 and B3 are located on the same side of the segment A, substantially in a parallel orientation.

The conductive trace A is formed on an isolation area “a1”, and the conductive trace segment B1, the conductive trace segment B2 and the conductive trace B3 are formed on isolation areas “b1”, “b2” and “b3”, respectively. It is appreciated that the isolation area a1 is wider than the trace Al and that the isolation areas b1, b2 and b3 are wider than the traces B1, B2 and B3, respectively, thereby ensuring that the conductive traces A, B1, B2 and B3 are electrically isolated from the substrate 12002.

It is further appreciated that the trace A is sufficiently disposed from terminal ends 12001, 12003 and 12005 of segments B1, B2 and B3, respectively, such that line A traverses between the segments B1 and the segments B2 and B3 without electrically shorting to the line segments B1, B2 and B3. FIG. 38 shows that the conductive trace line A passes between the separated trace segments B1, and B2 and B3 and thus the conductive trace A is electrically isolated from the conductive traces B1, B2 and B3.

The isolation areas b1, b2 and b3 extend beyond their corresponding segment B1, B2 and B3, respectively. In addition, the traces B1, B2 and B3 and their respective isolation areas b1, b2 and b3 extend into the crossing area 12006.

Dashed lines 12010 12012 schematically show that the segment B1 is electrically connected to the segment B2 and the segment B3, respectively.

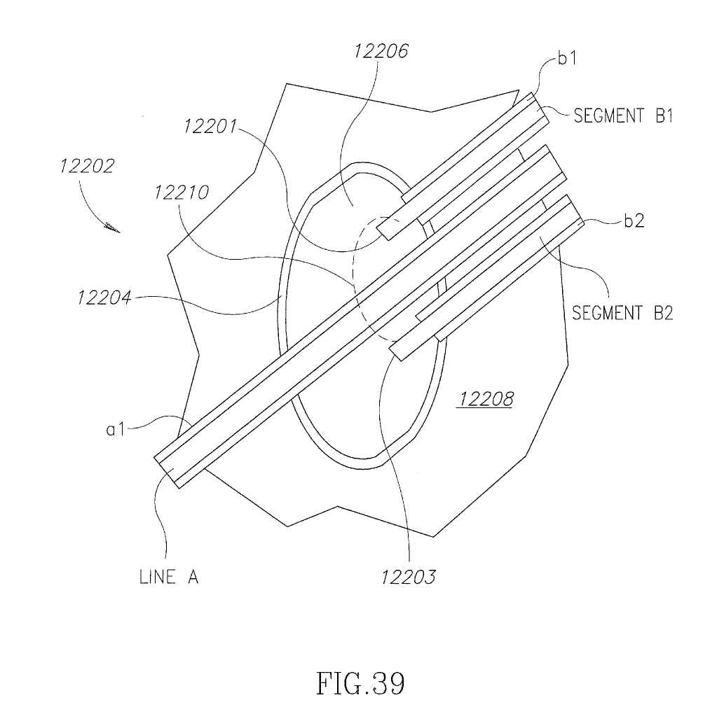

Reference is now made to FIG. 39, which shows a view of a substrate 12202, in accordance with another preferred embodiment of the present invention. A vertical isolation closed structure 12204 encompasses an isolated crossing area 12206. Crossing area 12206 extends through substrate 12202 from an upper surface 12207 (not shown) to a lower surface 12208 of substrate 12202.

A continuous and unsegmented conductive trace “A” and a segmented conductive trace “B” are formed the lower surface 12208 of the substrate 12202. The trace A and the segmented trace B are typically coplanar. The segmented conductive trace B includes at least two segments “B1” and “B2”, which are separated by the trace A. The conductive traces B1 and B2 extend within the crossing area 12206.

The conductive trace A is formed on an isolation structure “a1”, and the conductive trace segment B1 and the conductive trace segment B2 are formed on isolation areas “b1” and “b2”, respectively. It is appreciated that the isolation area a1 is wider than the trace A1 and that the isolation areas b1 and b2 are wider than the traces B1 and B2, respectively, thereby ensuring that the conductive traces A, B1 and B2 are electrically isolated from the substrate 12002. The traces A, B1 and B2 and their respective isolation areas a1, b1 and b2 extend into the crossing are 12206.

It is further appreciated that the trace A is sufficiently disposed from terminal ends 12201 and 12203 of segments B1 and B2, respectively, such that line A traverses between the segments B1 and B2 without electrically shorting to the line segments B1 and B2. FIG. 39 shows that the conductive trace line A passes between the separated trace segments B1 and B2 and thus the conductive trace A is electrically isolated from the conductive traces B1 and B2.

As shown in FIG. 39, the conductive traces B1 and B2 are substantially in a parallel orientation to each other and the trace A passes therebetween. A dashed line 12210 schematically shows that in accordance with the preferred embodiment of the present invention, the at least two conductive trace segments B1 and B2 are electrically connected.

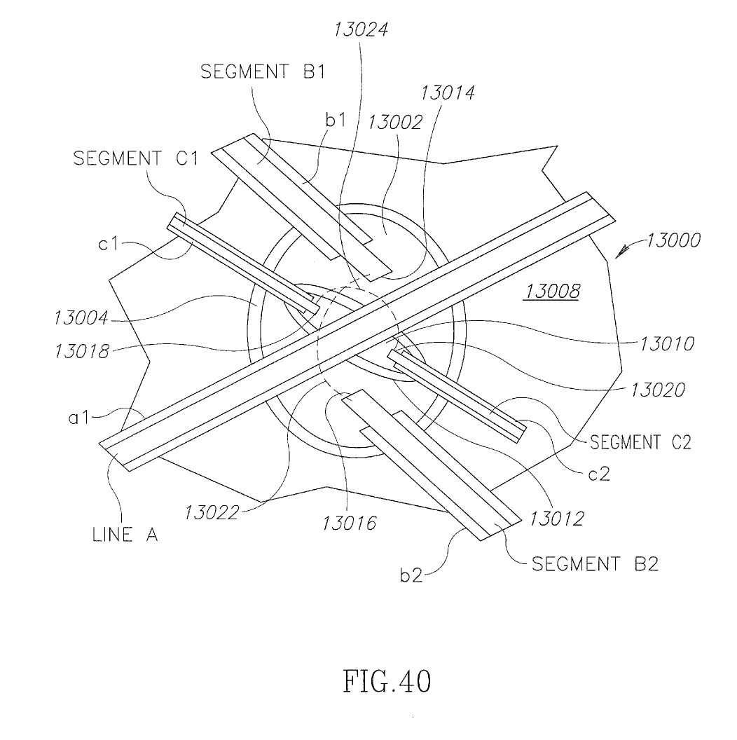

Reference is now made to FIG. 40, which shows a view of a substrate 13000, in accordance with yet a further preferred embodiment of the present invention. A first vertical isolation closed structure 13004 encompasses a first isolated crossing area 13002. The first crossing area 13002 extends through substrate 13000 from an upper surface 13006 (not shown) to a lower surface 13008 of the substrate 13000. Additionally, the substrate 13000 includes a second isolated crossing area 13010 located on the lower surface 13008 and encompassed by a second vertical isolation closed structure 13012. The second crossing area 13010 extends through substrate 13000 from the upper surface 13006 (not shown) to the lower surface 13008 of the substrate 13000.

A continuous and unsegmented conductive trace “A”, a segmented conductive trace “B” and a segmented trace “C” are formed the lower surface 13008 of the substrate 13000. The continuous trace A and the segmented traces B and C are typically coplanar. The segmented conductive trace B includes at least two segments “B1” and “B2”, which are separated by the trace A. In addition, the segmented conductive trace C includes at least two segments “C1” and “C2”, which are also separated by the trace A.

It is shown in FIG. 40 that the conductive traces B1 and B2 extend into the first crossing area 13002 and the conductive traces C1 and C2 extend into the second crossing area 13010.

The conductive trace A is formed on an isolation structure “a1”, the conductive trace segment B1 and the conductive trace segment B2 are formed on isolation areas “b1” and “b2”, respectively. Additionally, the conductive trace segment C1 and the conductive trace segment C2 are formed on isolation areas “c1” and “c2”, respectively. It is appreciated that the isolation area a1 is wider than the trace A1, the isolation areas b1 and b2 are wider than the traces B1 and B2, respectively and the isolation areas c1 and c2 are wider than the traces C1 and C2, respectively.

Thus, the segmented traces B1 and B2 and are electrically isolated from the substrate 13000 as well as from the segmented traces C1 and C2. Similarly, the segmented traces C1 and C2 are electrically isolated from the substrate 13000 as well as from the segmented traces B1 and B2.

In FIG. 40 it is also shown that the traces B1 and B2 and their respective isolation areas b1 and b2 extend into the first crossing 13002 and the traces C1 and C2 and their respective isolation areas c1 and c2 extend into the second crossing area 13010.

It is appreciated that the trace A is sufficiently disposed from terminal ends 13014 and 13016 of segments B1 and B2, respectively and terminal ends 13018 and 13020 of segments C1 and C2, respectively such that line A traverses between the segments B1 and B2 and between the segments C1 and C2 without electrically shorting to the line segments B1 and B2 and the line segments C1 and C2. It is further shown in FIG. 40 that the conductive trace line A passes between the separated trace segments B1 and B2 and the separated trace segments C1 and C2. Thus the conductive trace A is electrically isolated from the conductive traces B1 and B2 and conductive traces C1 and C2.

A dashed line 13022 schematically shows that the segment B1 and the segment B2 are electrically connected and a dashed line 13024 schematically shows that the segments C1 and C2 electrically connected.

It is appreciated that although the present embodiment relates to a continuous trace, such as trace A, and at least two segmented traces, such as trace B and trace C, the present invention is applicable for cross-over devices including a plurality of continuous traces and a plurality of segmented traces.

### Applications

The products and processes disclosed herein may be used in a wide variety of applications including, but not limited to the following:

### Family A—LED Related

The Die
Any LED or LED assembly/exerting peak thermal power of over 0.3 (still need to think over this value—uri) Watts/sq cm of the bottom LED/LED assembly area (maybe a packaged LED, or LED assembly)(probably this definition includes all the other LEDs mentioned below;
   LED
   High Brightness LED
   OLEDs (Organic LED) sometimes named PLEDs (Polymer LEDs)

The Package/Module/SiP/MCP:
one packaged LED
set of several LEDs or same substrate
Array of LEDS assembled onto a substrate

Applications/Use:
1. Automotive Applications
   Internal lighting
   Exterior lighting
   Dash/LCD backlight
2. Signs and Displays (in houses; and outdoors)
3. Backlight Units (BLU) for
   TV screens
   Computer displays
   Laptop displays
   Portable Electronics (such as cellphone, PDAs,) displays
4. General Lighting
   Architectural lighting (in homes, and outside lightning)
   Underwater lighting
   Inground, luminairs
   Personal light projectors

It should be noted that, for LEDs, the ALOX™ substrate is useful for both direct assembly of the LEDs and also for assembly of the power devices used in various driver modules used to drive in/out the currents/voltage to operate the LEDs as in Family A as in Family B below. In this regard, the ALOX™ substrate can be used to assemble LEDs and a driver module to operate the LEDs.

### Family B—Power Drivers/Power Modules Related

A) THE DIE—The high power (hot) die embedded in the package/module:
Any device or die/exerting peak thermal power of over 0.3 Watts/sq cm of bottom die/device area (device maybe a packaged die, a module for itself) (probably this definition includes all the other dies mentioned below)
   Power MOSFETs or
   IGBT discrete;
   Power BJTs (Bipolar Junction Transistor)

B) The Package/Module
Power die (as listed above) in single die Package or
Power Module/SIP (System in Package)/MCP (Multi Chip Package) (containing hot die as above, or not containing hot die in list above) such as:
   DC/DC converters
   DC/AC inverter
   AC/DC inverter
   IGBT module
   Smart Power Module
   Low Voltage (up to 200 Volts) motor controllers
   Power Controller
   Power driver
   Power Switches
   LED driver
   Motor controller/driver
   RF Power modules, such as
      Power Amplifier

C) End Use/Application:
1) Automotive
   Motion control
   Ignition—coil and plug
   Dashboard
2) Industrial
   AC Motors
   Welding
3) Home Appliances such as:
   Refrigerators
   air conditioner,
   washing machines;
   vacuum cleaner;
   Fan motors
   LED based display
4) Portable Electronic Devices for Consumer Applications and Communication and Computing such as
   cellular phones—handsets and base-stations
   Laptop computers
   PDAs
   RF Power amplifiers are used in
   wireless LANs;
   cellular handsets
   base stations for cellular applications
   mm wave components for applications such as point to point or point to multipoint radio)
   LCD (Liquid Crystal Display) displays—interface and control
   PDP (Plasma Display Panels) displays—interface and control

It is noted that the terms “isolation area” and “isolation trace” may be used interchangeably.

It is further noted that the terms “crossing area” and “crossing region” may be used interchangeably.

It will be apparent to those skilled in the art that various modifications and variation can be made to the techniques described in the present disclosure. Thus, it is intended that the present disclosure covers the modifications and variations of the techniques, provided that they come within the scope of the appended claims and their equivalents.

What is claimed is:

1. An electrical cross-over device comprising:
a substrate having an upper surface and a lower surface;
an electrically-conductive valve metal crossing area extending from said upper surface to said lower surface;
an electrical isolation structure extending from said upper surface to said lower surface and encompassing said electrically conductive crossing area;
a first electrically-conductive trace formed on a first electrical isolation area and at least traversing said electrically-conductive crossing area, and
at least two second electrically-conductive traces each one of said at least two electrically-conductive traces is formed on a corresponding second electrical isolation trace,
wherein said each one of said at least second electrically-conductive traces at least partially extends into said crossing area beyond corresponding second electrical isolation traces, thereby generating electrical conductivity between said at least two second electrically-conductive traces and said first electrically-conductive trace is electrically isolated from said at least two second electrically-conductive traces.

2. The electrical cross-over device according to claim 1, wherein at least one of said corresponding second isolation areas terminates in contact with said isolation structure.

3. The electrical cross-over device according to claim 1, wherein at least one of said at least two second conductive traces comprises at least one expanded conduction region located within said crossing area.

4. The electrical cross-over device according to claim 3, wherein said corresponding second isolation area abuts said first isolation trace.

5. The electrical cross-over device according to claim 1, wherein said at least two second electrically-conductive traces are coplanarly located on opposite sides of said first conductive trace.

6. The electrical cross-over device according to claim 1, wherein said at least two second electrically-conductive traces are substantially in a parallel orientation to said first conductive trace.

7. The electrical cross-over device according to claim 1, wherein said at least two second electrically-conductive traces are located on same side of said first conductive trace.

8. The electrical cross-over device according to claim 1, wherein said electrical isolation structure has a geometrical shape said geometrical shape is selected from the group consisting of a rectangular cross-sectional are, a square cross-sectional area, a circular cross-sectional area, an ellipsoidal cross-sectional area, a polygonal cross-sectional area and any combination thereof

9. The electrical cross-over device according to claim 1, wherein said electrical isolation structure has a geometrical shape that varies between said upper surface and said lower surface.

10. The electrical cross-over device according to claim 1, wherein said electrical isolation structure comprises a valve metal oxide.

11. The electrical cross-over device according to claim 1, wherein said crossing area comprises a cavity.

12. A method for electrical cross-over comprising:
providing a valve metal substrate having an upper surface and a lower surface;
selectively anodizing said substrate to form:
a closed electrical isolation structure extending from said upper surface to said lower surface encompassing an electrically conductive area which extends from said upper surface to said lower surface;
a first electrical isolation area traversing said electrically-conductive crossing area; and
at least two second electrical isolation areas;
applying a first metallization trace on said first electrical isolation area;
applying at least two second metallization traces on said at least two second electrical isolation areas;
wherein said each one of said at least second metallization traces at least partially extends into said crossing area thereby generating electrical conductivity between said at least two second metallization traces and said first metallization trace is electrically isolated from said at least two second metallization traces.

13. The method according to claim 12, wherein at least one of said second isolation areas terminates while connecting to said isolation structure.

14. The method according to claim 12, wherein at least one of said at least two second metallization traces comprise at least one conduction region located within said crossing area.

15. The method according to claim 14, wherein said corresponding second isolation area abuts said first isolation area.

16. The method according to claim 12, wherein said at least two second electrically-metallization traces are coplanarly located on opposite sides of said first metallization trace.

17. The method according to claim 12, wherein said at least two metallization layers are substantially in a parallel orientation to said first conductive trace.

18. The method according to claim 12, wherein said electrical isolation structure has a geometrical shape said geometrical shape is selected from the group consisting of a rectangular cross-sectional are, a square cross-sectional area, a circular cross-sectional area, an ellipsoidal cross-sectional area, a polygonal cross-sectional area and any combination thereof

19. The method according to claim 12, wherein said electrical isolation structure as a geometrical shape that varies between said upper surface and said lower surface.

20. The method according to claim 12, further comprising forming a cavity on at least one of said upper surface or said lower surface prior to the step of anodizing.
